(19) United States
(12) Patent Application Publication
(10) Pub. No.: US 2026/0107758 A1
(43) Pub. Date: Apr. 16, 2026

(54) INTERCONNECTION STRUCTURE, AND METHOD FOR FABRICATING THE SAME

(71) Applicant: TAIWAN SEMICONDUCTOR MANUFACTURING COMPANY, LTD., Hsinchu (TW)

(72) Inventors: Shao-Kuan LEE, Hsinchu (TW); Ting-Ya LO, Hsinchu (TW); Hsin-Yen HUANG, Hsinchu (TW); Wei-Chen CHU, Hsinchu (TW); Hsiao-Kang CHANG, Hsinchu (TW)

(73) Assignee: TAIWAN SEMICONDUCTOR MANUFACTURING COMPANY, LTD., Hsinchu (TW)

(21) Appl. No.: 18/911,724

(22) Filed: Oct. 10, 2024

(51) Int. Cl. H01L 23/528; H01L 21/762; H01L 21/768; H01L 23/522

(52) U.S. Cl. CPC H10W 20/435; H10W 10/0145; H10W 10/17; H10W 20/056; H10W 20/42

(57) ABSTRACT

A method is provided for fabricating an interconnection structure. A first metal layer is formed over a semiconductor substrate. The first metal layer is patterned to form a first metal line and a second metal line. An interlayer dielectric layer is deposited over the first metal line and the second metal line, where the interlayer dielectric layer has a first air gap disposed between the first metal line and the second metal line. A via hole is formed in the interlayer dielectric layer, where the via hole exposes the first metal line. A metal via is formed in the via hole.

### BACKGROUND

The semiconductor integrated circuit (IC) industry has over the past decades experienced tremendous advancements and is still experiencing vigorous development. However, advances in IC design need to be accompanied by improvements in manufacturing in order to optimize device performance. As an example, interconnections between different layers of wires and associated dielectrics play an important role in IC performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a sectional view of an interconnection structure in accordance with a first embodiment.

FIG. 2 is a sectional view of an interconnection structure in accordance with a second embodiment.

FIG. 3 is a flow chart illustrating steps of a method for fabricating an interconnection structure in accordance with the second embodiment.

FIGS. 4 through 7 and 10 through 13 are sectional views illustrating intermediate structures formed during performing of the method for fabricating an interconnection structure in accordance with the second embodiment.

FIG. 8 is a sectional view illustrating air gaps formed among metal lines in accordance with some embodiments.

FIG. 9 shows sectionals views comparing conformal deposition and non-conformal deposition in accordance with some embodiments.

FIGS. 14 and 15 respectively illustrate an X-cut view and a Y-cut view of an interconnection structure in accordance with a third embodiment.

FIG. 16 is a flow chart illustrating some steps of a method for fabricating an interconnection structure in accordance with the third embodiment.

FIGS. 17 through 27 are sectional views illustrating intermediate structures formed during performing of the method for fabricating an interconnection structure in accordance with the third embodiment.

FIG. 28 is a sectional view of an interconnection structure in accordance with a fourth embodiment.

FIG. 29 is a flow chart illustrating some steps of a method for fabricating an interconnection structure in accordance with the fourth embodiment.

FIGS. 30 through 36 are sectional views illustrating intermediate structures formed during performing of the method for fabricating an interconnection structure in accordance with the fourth embodiment.

FIGS. 37 and 38 respectively illustrate an X-cut view and a Y-cut view of an interconnection structure in accordance with a fifth embodiment.

FIGS. 39 through 51 are sectional views illustrating intermediate structures formed during performing of the method for fabricating an interconnection structure in accordance with the fifth embodiment.

FIG. 52 is a sectional view of an interconnection structure in accordance with a sixth embodiment.

FIGS. 53 and 54 respectively illustrate an X-cut view and a Y-cut view of an interconnection structure in accordance with a seventh embodiment.

FIG. 55 is a flow chart illustrating some steps of a method for fabricating an interconnection structure in accordance with the seventh embodiment.

FIG. 56 through 58 are sectional views illustrating intermediate structures formed during performing of the method for fabricating an interconnection structure in accordance with the seventh embodiment.

FIG. 59 is a sectional view of an interconnection structure in accordance with an eighth embodiment.

FIGS. 60 and 61 respectively illustrate an X-cut view and a Y-cut view of an interconnection structure in accordance with a ninth embodiment.

FIG. 62 is a sectional view of an interconnection structure in accordance with a tenth embodiment.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

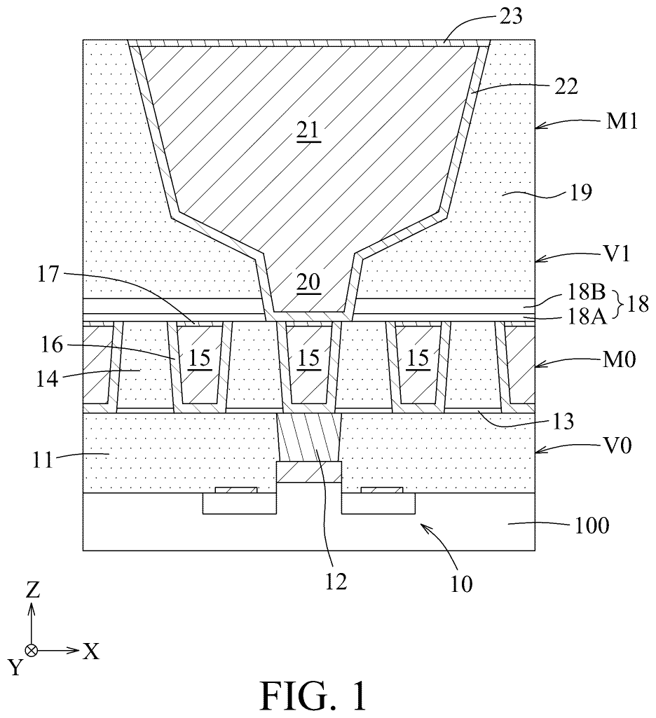

FIG. 1 illustrates an interconnection structure formed over a semiconductor substrate 100 in accordance with a first embodiment. The semiconductor substrate 100 may be a bulk semiconductor substrate or a semiconductor-on-insulator (SOI) substrate, which may be doped (e.g., with a p-type or an n-type dopant) or undoped. In some embodiments, an SOI substrate includes a layer of a semiconductor material formed on an insulator layer. The insulator layer may be a buried oxide (BOX) layer, a silicon oxide layer or any other suitable layer. The insulator layer may be provided on a suitable substrate, such as silicon, glass or the like. The semiconductor substrate 100 may be made of a suitable semiconductor material, such as silicon or the like. In some embodiments, the semiconductor substrate 100 is a silicon wafer; and in other embodiments, the semiconductor substrate 100 is made of a compound semiconductor such as silicon carbide, gallium arsenide, indium arsenide, indium phosphide or other suitable materials. In still other embodiments, the semiconductor substrate 100 is made of an alloy semiconductor such as GaAsP, AlInAs, AlGaAs, GaInAs, GaInP, GaInAsP or other suitable materials.

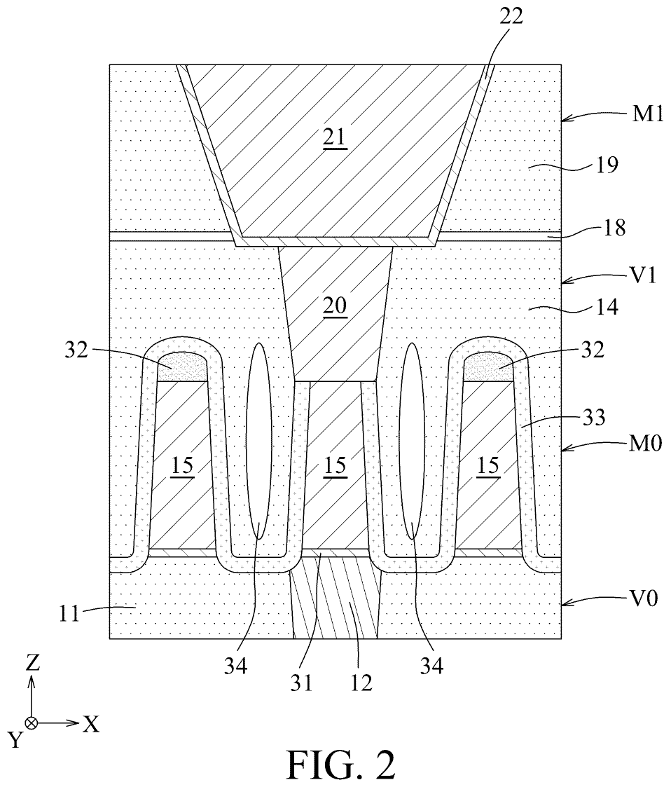

In some embodiments, the semiconductor substrate 100 includes various p-type doped regions and/or n-type doped regions, such as p-type wells, n-type wells, p-type source/drain features and/or n-type source/drain features, formed by a suitable process such as ion implantation, thermal diffusion, a combination thereof, or the like. In some embodiments, the semiconductor substrate 100 may include other functional elements such as resistors, capacitors, diodes, transistors, and/or the like. The transistors are, for example, field effect transistors (FETs), such as planar FETs and/or 3D FETs (e.g., FinFETs, GAAFETs). The semiconductor substrate 100 may include lateral isolation features (e.g., shallow trench isolation (STI)) configured to separate various functional elements formed on and/or in the semiconductor substrate 100. In the illustrative embodiment, the semiconductor substrate 100 is exemplified to include a transistor 10. It is noted that the semiconductor substrate 100 and the transistor 100 will be omitted in the following figures (e.g., FIGS. 2, 4-7, 10-15, 17-28, 30-54 and 56-62) for the sake of clarity. A via layer V0 is formed over the semiconductor substrate 100 and the transistor 10, and includes a plurality of metal vias formed in an interlayer dielectric (ILD) 11 and connected to multiple circuit nodes, such as gate nodes, source nodes and drain nodes of transistors, anodes and cathodes of diodes, etc. In the illustrative embodiment, the via layer V0 is exemplified to include a metal via 12 that is directly connected to a gate of the transistor 10, meaning that the metal via 12 connects to the gate of the transistor 10 without passing through any other metal lines or metal vias, although there may be other conductive thin films, such as barrier films or liner films, disposed between the metal via 12 and the gate. In accordance with some embodiments, the metal via 12 may include, for example, W, Mo, Co, Ru, other suitable conductive materials, or any combination thereof. A metal line layer M0 is disposed over the via layer V0, and includes a plurality of metal lines 15 formed in an ILD 14, which is separated from the ILD 11 by an etch stop layer (ESL) 13. In accordance with some embodiments, the metal lines 15 may include, for example, Cu, W, Mo, Co, Ru, other suitable conductive materials, or any combination thereof, and may be formed using, for example, a single damascene process, other suitable processes, or any combination thereof. Each of the metal lines 15 may have a width that gradually decreases from top to bottom, resulting in a wider top portion compared to its bottom portion, but this disclosure is not limited in this respect. In some embodiments, the width of the metal lines 15 may be uniform from top to bottom, depending on process control. In the illustrative embodiment, one of the metal lines 15 is directly connected to the metal via 12. A conductive barrier layer 16 is formed between the metal line 15 and the metal via 12, as well as between the metal line 15 and the ILD 14. Additionally, a cap layer 17 covers the metal line 15. In accordance with some embodiments, the conductive barrier layer 16 is used to prevent metal atoms in the metal line 15 from diffusing into the ILD 14, and may include, for example, TaN, TiN, other suitable materials, or any combination thereof. In accordance with some embodiments, the cap layer 17 is used as an adhesion layer and/or a barrier layer to prevent metal atoms from diffusing into adjacent layers, and may include, for example, Co, W, Ru, Mo, other suitable materials, or any combination thereof., A via layer V1 and a metal line layer M1 are formed in an ILD 19 over the metal line layer M0.The ILD 19 is separated from the ILD 14 by an etch stop layer 18. In accordance with some embodiments, the ILDs 11, 14, 19 may include, for example, SiOₓ, low-k materials (e.g., SiCOH), other suitable materials, or any combination thereof. The etch stop layer 18 may have a single-layer structure or a multi-layer structure. In the illustrative embodiment, the etch stop layer 18 includes a first layer 18A that may have better etching resistance, and a second layer 18B that may have better moisture resistance and/or better ability to prevent metal diffusion, but this disclosure is not limited in this respect. In accordance with some embodiments, the via layer V1 includes a plurality of metal vias connected to the metal lines of the metal line layer M0, and the metal line layer M1 includes a plurality of metal lines connected to the metal vias of the via layer V1. In the illustrative embodiment, the via layer V1 is exemplified to include a metal via 20 that is directly connected to one of the metal lines 15 (e.g., the one connected to the metal via 12), and the metal line layer M1 is exemplified to include a metal line 21 that is directly connected to the metal via 20. In accordance with some embodiments, the metal via 20 and the metal line 21 may include, for example, Cu, W, Mo, Co, Ru, other suitable conductive materials, or any combination thereof, and may be formed using, for example, a dual damascene process, other suitable processes, or any combination thereof. In the illustrative embodiment, the metal via 20 and the metal line 21 are formed in one piece, and each of the metal via 20 and the metal line 21 has a wider top portion compared to its bottom portion. A conductive barrier layer 22 is formed between the metal via 20 and the ILD 19, between the metal line 21 and the ILD 19, and between the metal via 20 and the metal line 15, thereby preventing metal atoms in the metal via 20 and the metal line 21 from diffusing into adjacent layers. Additionally, a cap layer 23 is formed over the metal line 21.

FIG. 2 illustrates an interconnection structure in accordance with a second embodiment. The second embodiment is similar to the first embodiment, and differs in that, in the second embodiment, each of the metal lines 15 of the metal line layer M0 has a width that gradually decreases from bottom to top, and a glue layer 31 is formed under each of the metal lines 15. The metal via 20 of the via layer V1 is directly connected to one of the metal lines 15 without a conductive barrier layer interposed therebetween, and the other metal lines 15 in FIG. 2 are covered by a hardmask feature 32. A cap layer 33 is conformally formed over the metal lines 15 and the hardmask features 32. The ILD 14 is formed with air gaps 34 that are disposed among the metal lines 15 for capacitance reduction. In particular, the air gaps 34 among the metal lines 15 have an oval cross section, which has a curved upper edge and a curved lower edge, and the upper edges of the air gaps 34 are higher than the metal lines 15. The metal via 20 of the via layer V1 is formed in the ILD 14 using a single damascene process. In accordance with embodiments, the metal via 20 may be formed using a conductive material that has a relatively low diffusivity, such as W, Mo, Co, Ru, etc., so it is not necessary to form a barrier layer between the metal via 20 and the ILD 14. Since materials used in the barrier layer usually have relatively high resistance compared to materials used in the metal vias and metal lines, omission of the barrier layer may reduce overall resistance of the interconnection structure. The metal line 21 of the metal line layer M1 is formed in the ILD 19 using another single damascene process. In accordance with some embodiments, the metal line 21 may include, for example, Cu, W, Mo, Co, Ru, other suitable conductive materials, or any combination thereof. Because the metal via 20 and metal line 21 are formed using separate single damascene processes, the gap fill depth or aspect ratio for each single damascene process is relatively shallow or small compared to forming both in one dual damascene process. This makes it less likely for voids to form in the metal via 20 and metal line 21, especially as the pitches among metal lines of the metal line layer M1 are small, which may cause narrow line widths and high aspect ratios for the gap fill. The separate single damascene processes can be used to form each set of via and metal line layers. That being said, they are particularly suitable for the set of via layer V0 and metal line layer M0, and the set of via layer V1 and metal line layer M1, because these layers are closest to underlying circuit elements and therefore usually have higher metal line densities and smaller pitches when compared to other via and metal line layers.

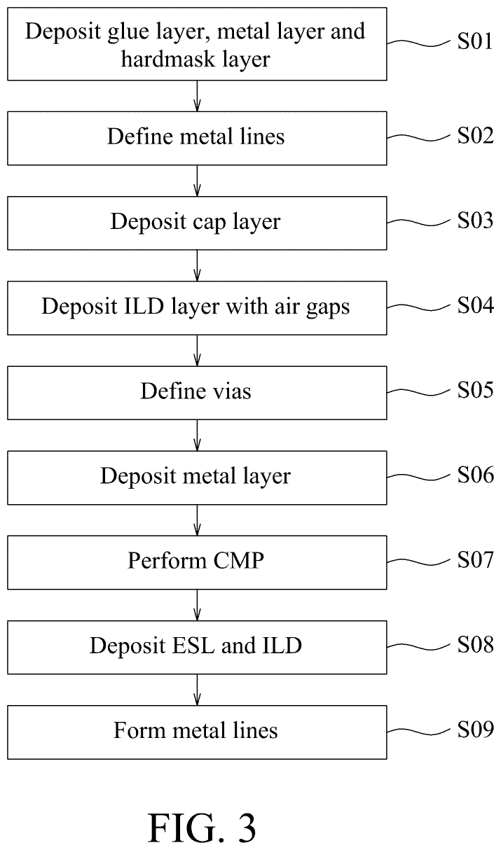

FIG. 3 is a flow chart illustrating steps of a method for fabricating an interconnection structure in accordance with the second embodiment.

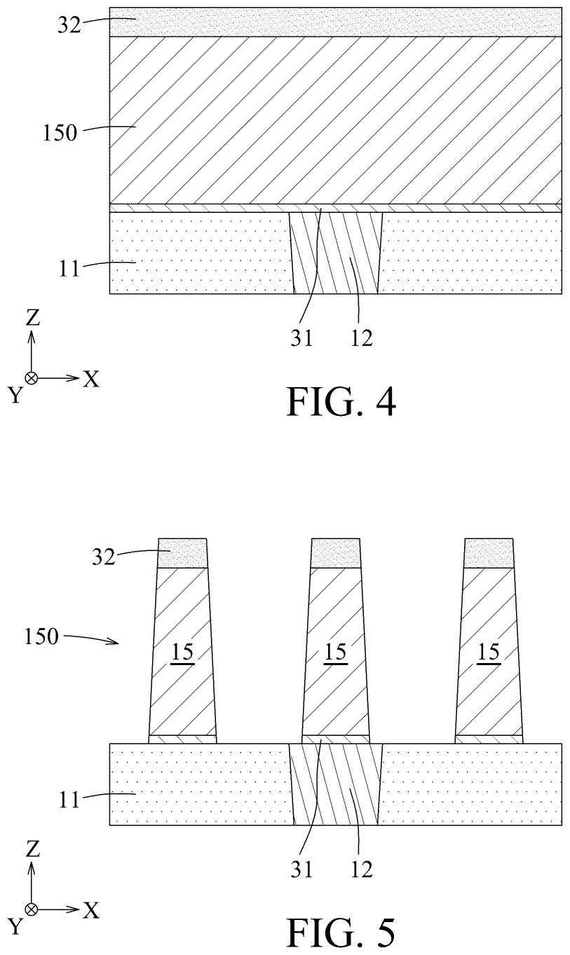

Referring to FIGS. 3 and 4, in step S01, a glue layer 31, a metal layer 150 and a hardmask layer 32 are deposited over the ILD 11 and the metal via 12 in sequence. In accordance with some embodiments, the glue layer 31 may include, for example, TiN, TaN, other suitable materials, or any combination thereof, and may be formed using, for example, physical vapor deposition (PVD), chemical vapor deposition (CVD), atomic layer deposition (ALD), other suitable deposition techniques, or any combination thereof. In accordance with some embodiments, the metal layer 150 may include, for example, W, Ru, Mo, other suitable materials, or any combination thereof, and may be formed using, for example, PVD, CVD, electrochemical plating (ECP), other suitable deposition techniques, or any combination thereof. In accordance with some embodiments, the hardmask layer 32 may include, for example, TiN, SiN, other suitable materials, or any combination thereof, and may be formed using, for example, PVD, CVD, plasma enhanced chemical vapor deposition (PECVD), ALD, plasma enhanced atomic layer deposition (PEALD), other suitable deposition techniques, or any combination thereof.

Referring to FIGS. 3 and 5, in step S02, the hardmask layer 32, the metal layer 150 and the glue layer 31 are patterned and etched through, for example, a lithography process, to form metal line stacks that define a plurality of metal lines 15. Each of the metal line stacks includes a portion of the glue layer 31, a portion of the metal layer 150 that serves as a metal line 15, and a portion of the hardmask layer 32, stacked over one another in the given sequence.

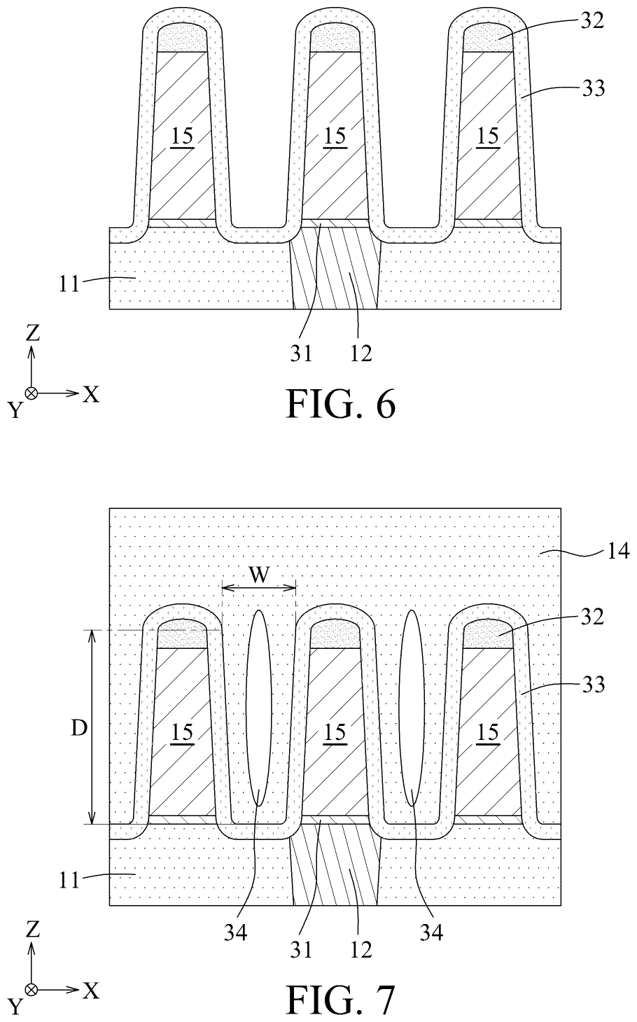

Referring to FIGS. 3 and 6, in step S03, a cap layer 33 is conformally deposited over the metal line stacks and the ILD 11. In accordance with some embodiments, the cap layer 33 may include, for example, elements such as Si, O, C, N, other suitable elements, or any combination thereof (e.g., SiOC, SiOCN, SiCN, etc.), and may be formed using, for example, CVD, PECVD, ALD, PEALD, other suitable deposition techniques, or any combination thereof. In accordance with some embodiments, the cap layer 33 may have a thickness in a range from about 10 angstroms to about 30 angstroms, so as to effectively protect the metal lines 15 from oxidation during the subsequent deposition of the ILD 14 (see FIG. 2).

Referring to FIGS. 3 and 7, in step S04, an ILD 14 is deposited over the cap layer 33 and the metal line stacks in a non-conformal manner, thereby forming air gaps (or voids) 34 in the ILD 14 at positions between the metal line stacks. In accordance with some embodiments, the non-conformal ILD 14 may be formed using, for example, CVD, PECVD, other suitable deposition techniques, or any combination thereof. It should be noted that it would be easier to form an air gap 34 between adjacent metal line stacks when a recess between the metal line stacks is narrow and/or has a high aspect ratio. In accordance with some embodiments, the recess may have a top width (i.e., a spacing (W) between two portions of the cap layer 33 that are disposed respectively on top parts of two opposing sidewalls respectively of the adjacent metal line stacks) smaller than 20 nm. In accordance with some embodiments, the recess may have an aspect ratio (D/W) greater than 0.7.

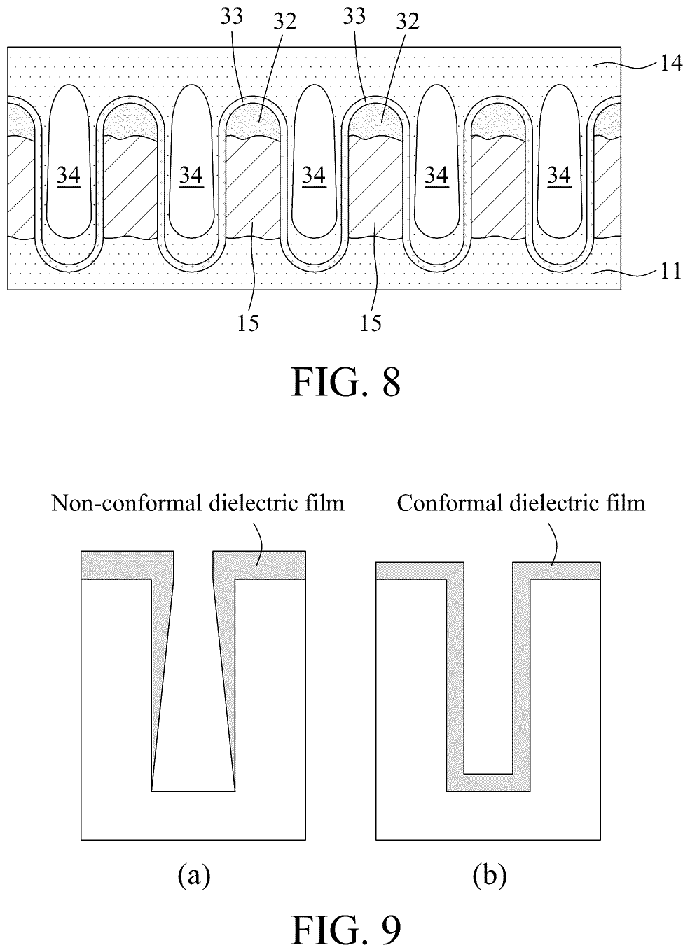

FIG. 8 illustrates profiles of the air gaps 34 that were actually made through the abovementioned process. Each of the metal lines 15 has a rectangular cross section and a uniform/constant width in a vertical direction. The air gaps 34 are taller than the metal line stacks, and have a cross section in an oval shape. Specifically, each of the air gaps 34 in FIG. 8 has an upper portion that is narrower than its intermediate portion and lower portion.

FIG. 9 compares dielectric films that are respectively deposited in the non-conformal manner and the conformal manner. Part (a) of FIG. 9 illustrates a dielectric film formed by the non-conformal deposition, such as CVD or PECVD, where precursors and/or reactive species may have difficulty penetrating deep into the recess, especially when the recess is narrow or has a high aspect ratio. As a result, the dielectric film tends to grow faster on the upper sidewalls than on the lower sidewalls and the bottom of the recess. Eventually, the dielectric film merges at the upper portion of the recess while the lower portion remains unfilled, thereby forming an air gap. Part (b) of FIG. 9 illustrates a dielectric film formed by the conformal deposition, such as ALD, where the dielectric film grows uniformly everywhere, and thus no air gaps would be formed.

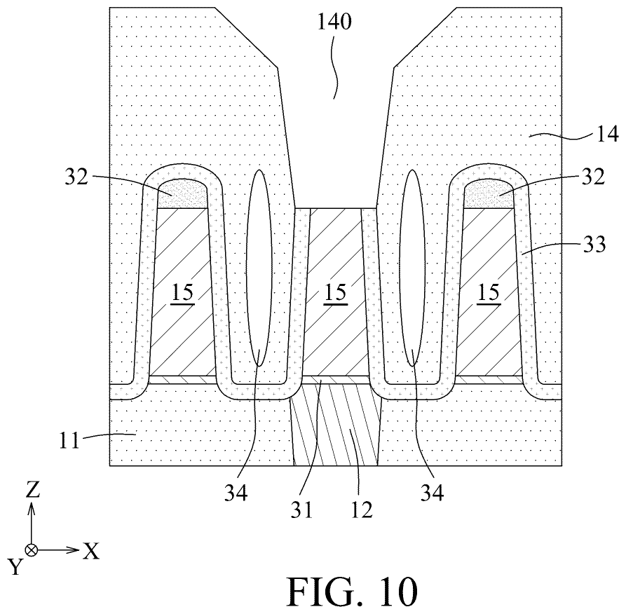

Referring to FIGS. 3 and 10, in step S05, the ILD 14 is patterned and etched to form via holes to define vias through, for example, a lithography process. In FIG. 10, only one via hole 140 is illustrated, but this disclosure is not limited in this respect. The via hole 140 is formed by etching the ILD 14, the cap layer 33 and the hardmask layer 32, thereby exposing the underlying metal lines 15.

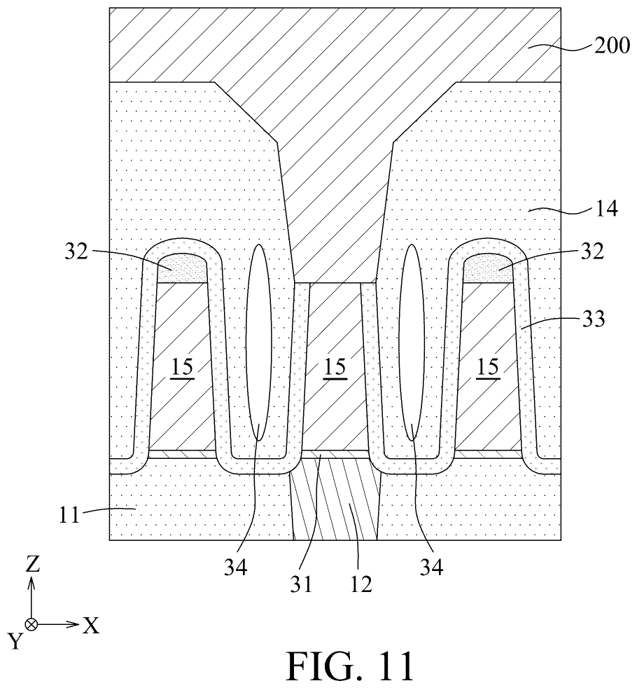

Referring to FIGS. 3 and 11, in step S06, a metal layer 200 is deposited to fill the via hole 140 (see FIG. 10). In the illustrative embodiment, since no barrier layer is formed before the metal layer 200, the metal layer 200 may use conductive materials with a smaller diffusivity, such as W, Mo, Ru, other suitable materials, or any combination thereof, and may be formed using, for example, PVD, CVD, PECVD, ALD, PEALD, ECP, other suitable deposition techniques, or any combination thereof.

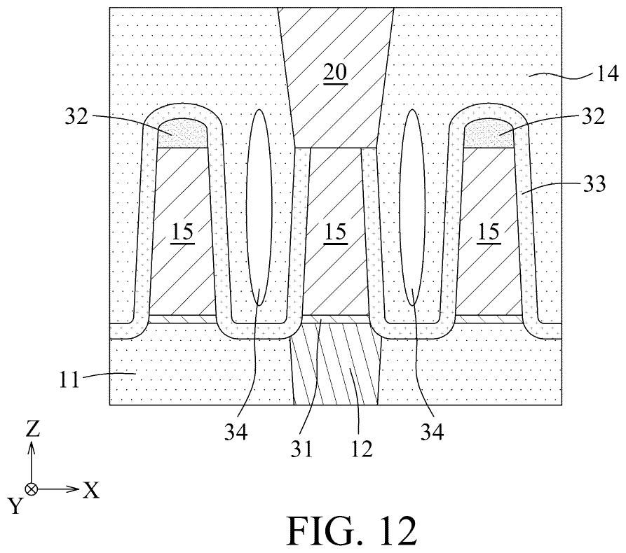

Referring to FIGS. 3 and 12, in step S07, a chemical-mechanical planarization (CMP) process is performed to remove excessive portions of the metal layer 200 (see FIG. 11), thereby forming a metal via 20 that is directly connected to or in contact with the underlying metal line 15.

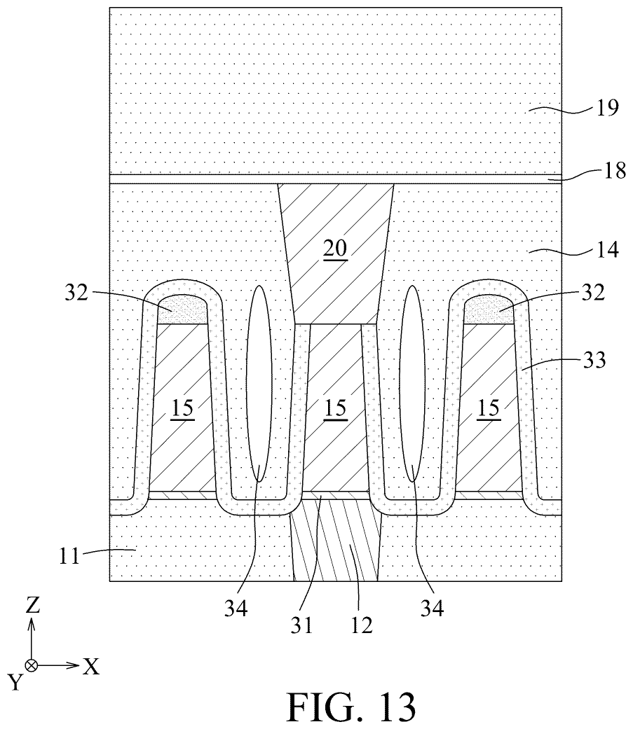

Referring to FIGS. 3 and 13, in step S08, an etch stop layer 18 and an ILD 19 are deposited over the metal via 20 and the ILD 14. In accordance with some embodiments, the etch stop layer 18 may include, for example, elements such as Al, Si, O, C, N, other suitable elements, or any combination thereof (e.g., AlN, AlON, AlOₓ, AlOC, AlOCN, etc.), and may be formed using, for example, PVD, CVD, PECVD, ALD, PEALD, other suitable deposition techniques, or any combination thereof.

In step S09, the ILD 19 and the etch stop layer 18 is patterned and etched to form a recess that exposes the metal via 20, and a barrier layer 23 and a metal layer are deposited to fill the recess, followed by a CMP process, thereby forming the metal lines (e.g., the metal line 21) in the metal line layer M1, as illustrated in FIG. 2.

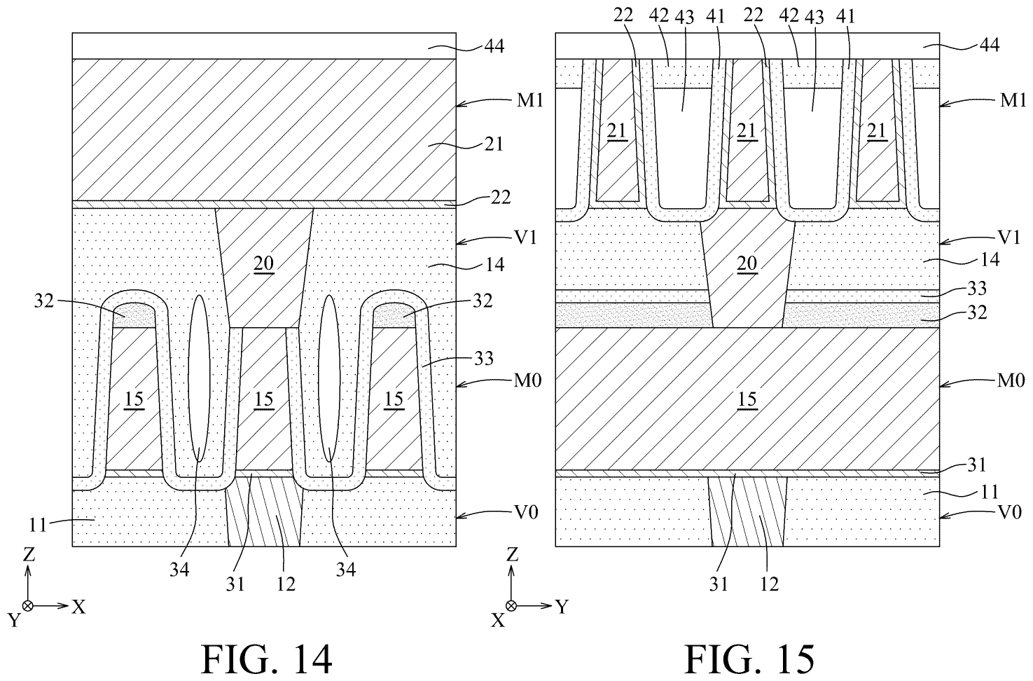

FIGS. 14 and 15 respectively illustrate an X-cut view (i.e., sectional view along the X-axis) and a Y-cut view (i.e., sectional view along the Y-axis) of an interconnection structure in accordance with a third embodiment, which is similar to the second embodiment. In the third embodiment, the metal line layer M1 is exemplified to include a plurality of metal lines 21 that extend in an X-axis direction and that are spaced apart from each other in a Y-axis direction. Each of the metal lines 21 has width that gradually decreases from bottom to top, and thus has a wider bottom portion compared to its top portion. Adjacent metal lines 21 are separated by a dielectric layer 42 and an air gap 43, where the air gap 43 is formed for reducing capacitance between the metal lines 21, and is disposed under and covered by the dielectric layer 42. In particular, the air gap 43 is shorter than the metal lines 21 in height, and has a polygonal cross section. In the illustrative embodiment, the air gap 43 has a trapezoidal cross section that has a straight upper edge and a straight lower edge, and that has a wider top portion compared to its bottom portion. A conductive barrier layer 22 is formed on a bottom and sidewalls of each metal line 21, thereby preventing metal atoms in the metal line 21 from diffusing into adjacent layers, such as the ILD 14 and the dielectric layer 42. A cap layer 41 is conformally disposed on the sidewalls of the metal lines 21 and between the metal lines 21, thus having a U-shaped profile between adjacent metal lines 21. The dielectric layer 42 and the air gap 43 are positioned between the opposing legs of the U-shaped cap layer 41. An etch stop layer 44 is disposed over the metal lines 21 and the ILD 42.

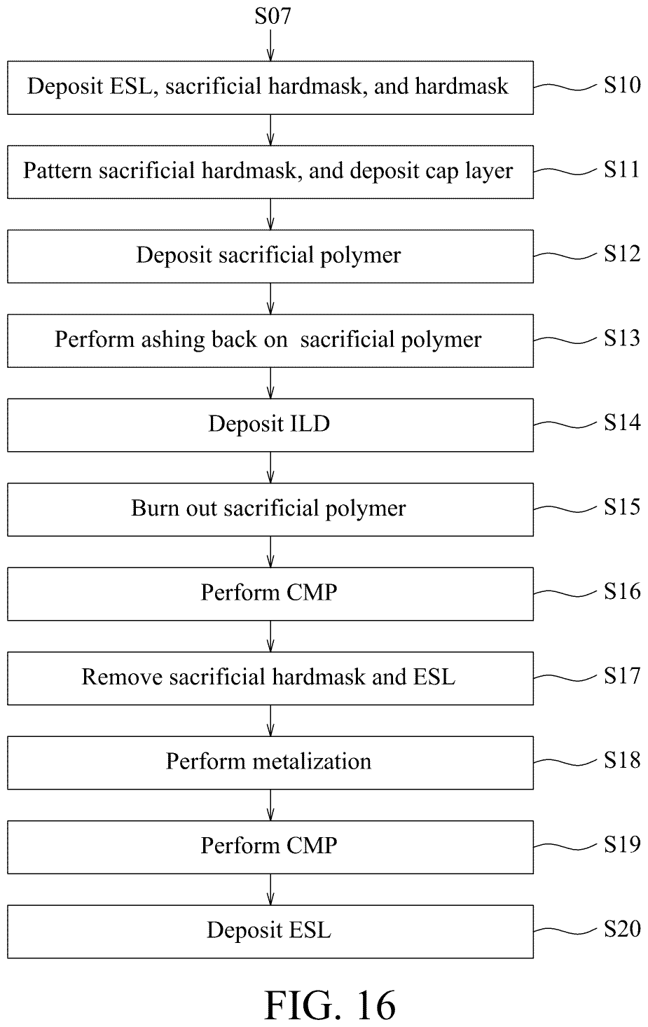

FIG. 16 is a flow chart illustrating some steps of a method for fabricating an interconnection structure in accordance with the third embodiment. Particularly, the method includes aforesaid steps S01 to S07 as shown in FIG. 3, and steps S10 to S20 following step S07. Accordingly, details of steps S01 to S07 are not repeated herein for the sake of brevity.

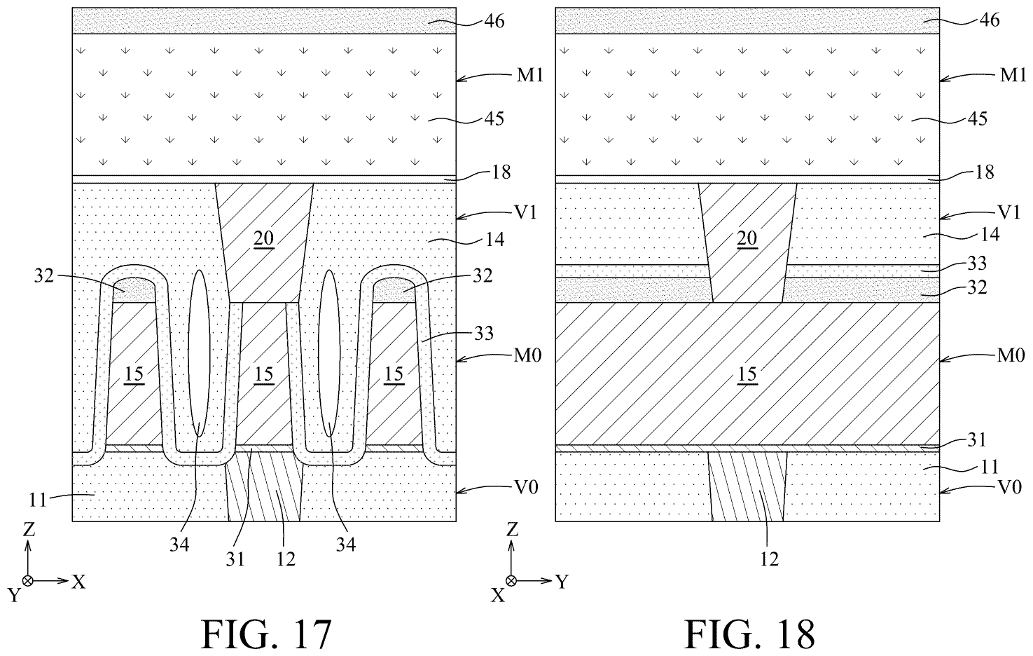

Referring to FIGS. 16, 17 and 18, in step S10, an etch stop layer 18, a sacrificial hardmask layer 45 and a hardmask layer 46 are deposited over the ILD 14 and the metal via 20 in the given order, where FIG. 17 is an X-cut view and FIG. 18 is a Y-cut view. In accordance with some embodiments, the sacrificial hardmask layer 45 may include, for example, TiN, other suitable materials, or any combination thereof, and may be formed using, for example, PVD, CVD, PECVD, ALD, PEALD, other suitable deposition techniques, or any combination thereof. In accordance with some embodiments, the hardmask layer 46 may include, for example, SiOₓ, other suitable materials, or any combination thereof, and may be formed using, for example, PVD, CVD, PECVD, ALD, PEALD, other suitable deposition techniques, or any combination thereof.

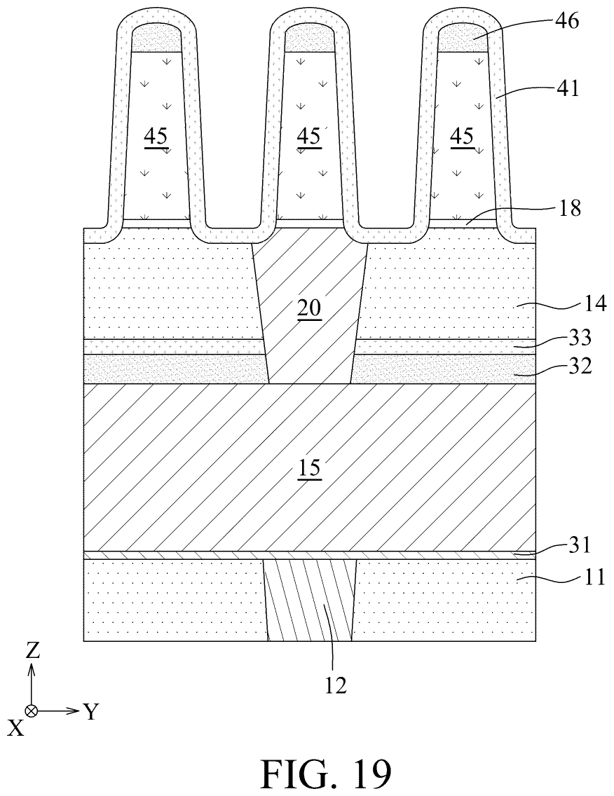

Referring to FIGS. 16 and 19, in step S11, the hardmask layer 46, the sacrificial hardmask layer 45 and the etch stop layer 18 are patterned and etched through, for example, a lithography process, thereby forming a plurality of dummy line stacks that define metal lines 21 to be formed in the metal line layer M1, as shown in FIG. 15. Each of the dummy line stacks has a width that gradually decreases from bottom to top because of the etching process, and thus has a wider bottom portion compared to its top portion. Then, a cap layer 41 is conformally deposited on the dummy line stacks. In accordance with some embodiments, the cap layer 41 may include, for example, elements such as Si, O, C, N, other suitable elements, or any combination thereof (e.g., SiOC, SiOCN, SiCN, etc.), and may be formed using, for example, CVD, PECVD, ALD, PEALD, other suitable deposition techniques, or any combination thereof. In accordance with some embodiments, the cap layer 41 may have a thickness in a range from about 10 angstroms to about 30 angstroms, so as to effectively preserve the pattern of the dummy line stacks after the sacrificial hardmask layer 45 is removed in subsequent steps.

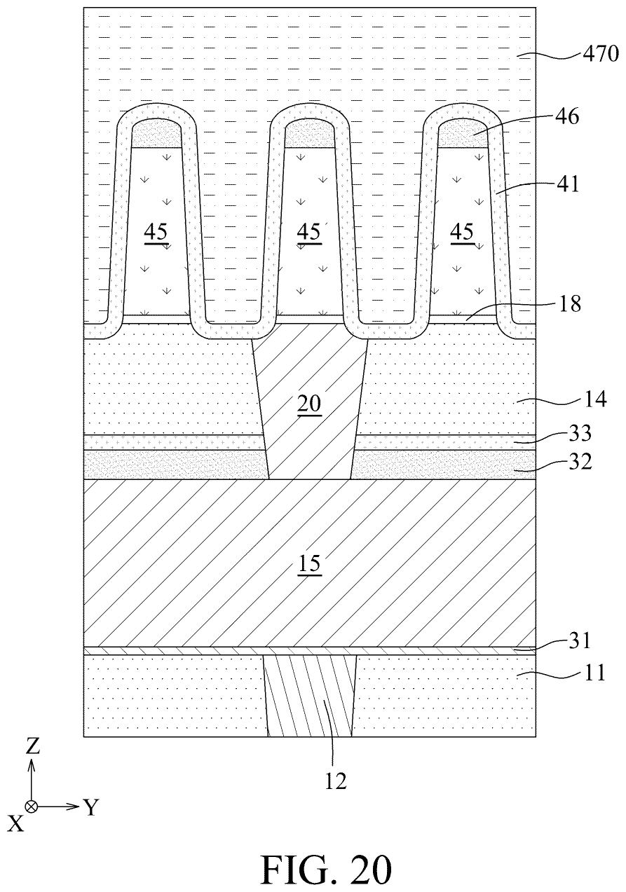

Referring to FIGS. 16 and 20, in step S12, a sacrificial polymer layer 470 is deposited over the cap layer 41 and filled in between the dummy line stacks. In accordance with some embodiment, the sacrificial polymer layer 470 may include, for example, elements such as C, N, O, H, other suitable elements, or any combination thereof, and may be formed using, for example, CVD, ALD, spin-on, other suitable techniques, or any combination thereof.

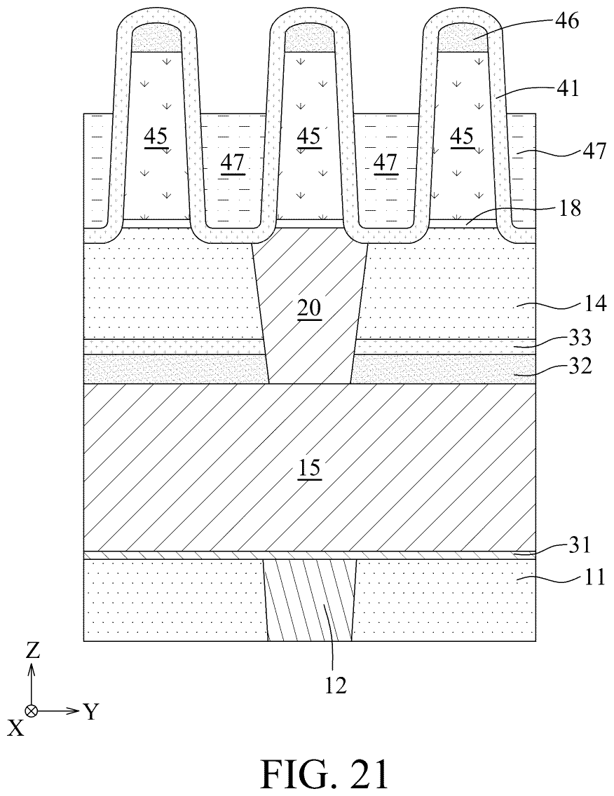

Referring to FIGS. 16 and 21, in step S13, an ashing back process is performed using, for example, a thermal process, an ultraviolet (UV) process, a dry plasma process, other suitable techniques, or any combination thereof, thereby partially removing the sacrificial polymer layer 470 (see FIG. 20) to form a plurality of sacrificial polymer features 47 among the dummy line stacks. Each of the sacrificial polymer features 47 has a top surface lower than a top surface of the sacrificial hardmask layer 45 of each of the dummy line stacks.

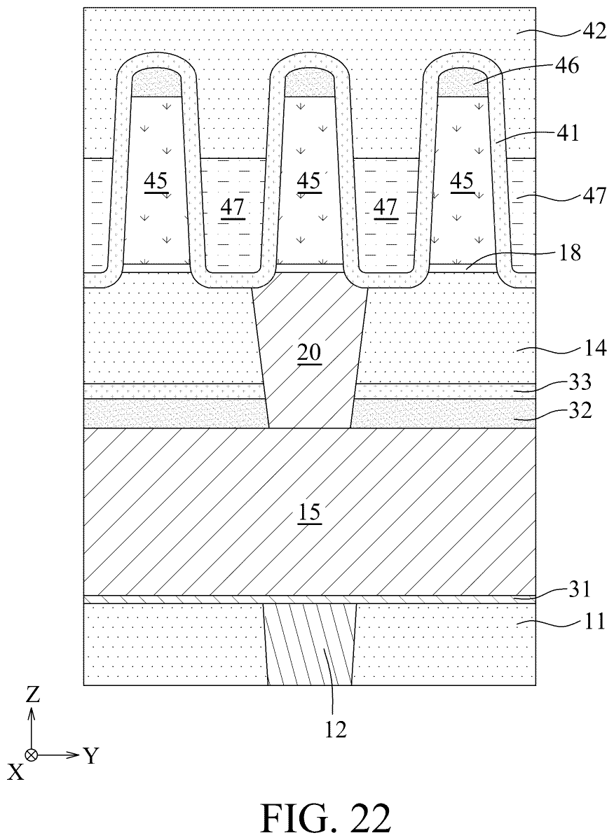

Referring to FIGS. 16 and 22, in step S14, a dielectric layer 42 is deposited over the cap layer 41, the sacrificial polymer features 47 and the dummy line stacks. In accordance with some embodiments, the dielectric layer 42 may include, for example, SiOₓ, low-k materials (e.g., SiCOH), other suitable materials, or any combination thereof, and may be formed using, for example, PVD, CVD, PECVD, ALD, PEALD, other suitable deposition techniques, or any combination thereof.

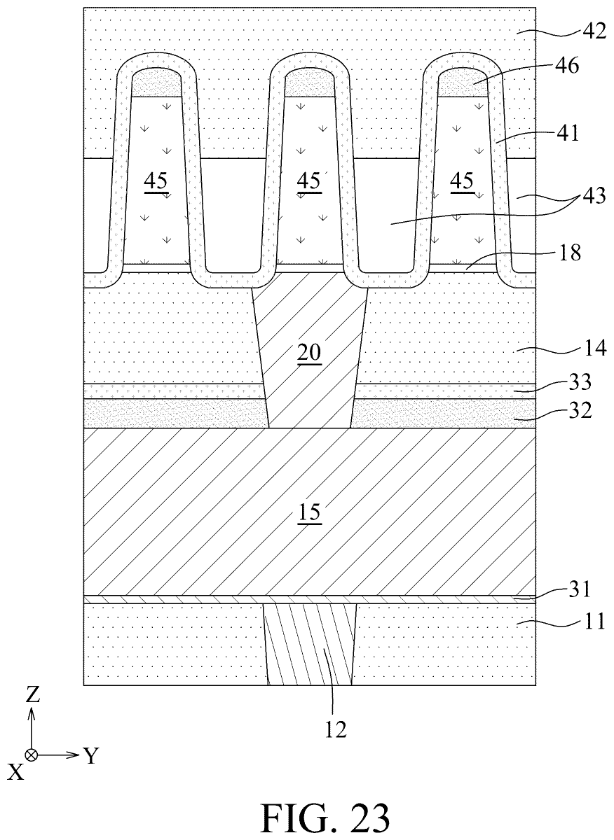

Referring to FIGS. 16 and 23, in step S15, the sacrificial polymer features 47 (see FIG. 22) are burnt out using, for example, a thermal process, a UV process, other suitable techniques, or any combination thereof, while the dielectric layer 42 remains, with a bottom surface lower than a top surface of the sacrificial hardmask layer 45. As a result, a plurality of air gaps (or voids) 43 are formed among the dummy line stacks and under the dielectric layer 42. In order to facilitate the outgassing and complete removal of the decomposed sacrificial polymer features 47 during the burning out process, the dielectric layer 42 may be permeable or porous in this embodiment.

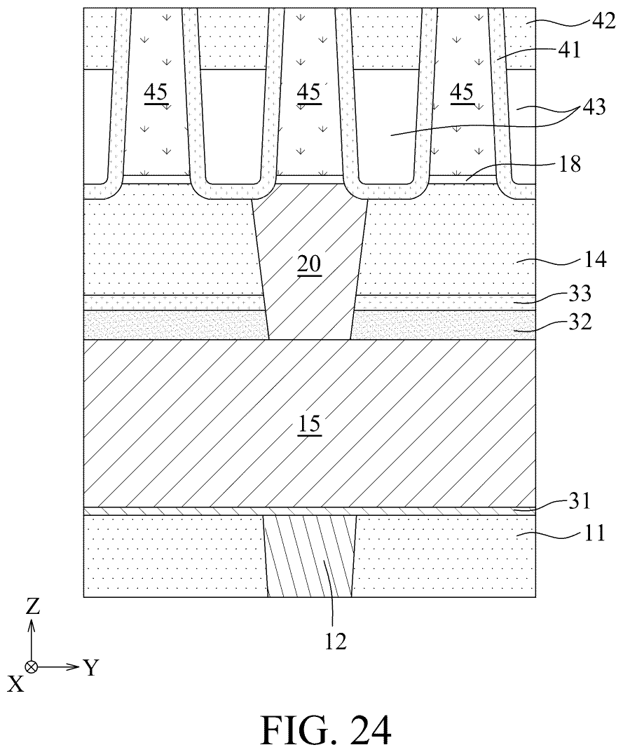

Referring to FIGS. 16 and 24, in step S16, a CMP process is performed to remove an upper part of the dielectric layer 42, an upper part of the cap layer 41, and the hardmask layer 46 (see FIG. 23), thereby exposing the patterned sacrificial hardmask layer 45 that is formed to include a plurality of hardmask lines (sacrificial hardmask features). The CMP process divides the dielectric layer 42 into multiple separate parts that respectively cover and preserve the air gaps 43, and divides the cap layer 41 into multiple separate segments.

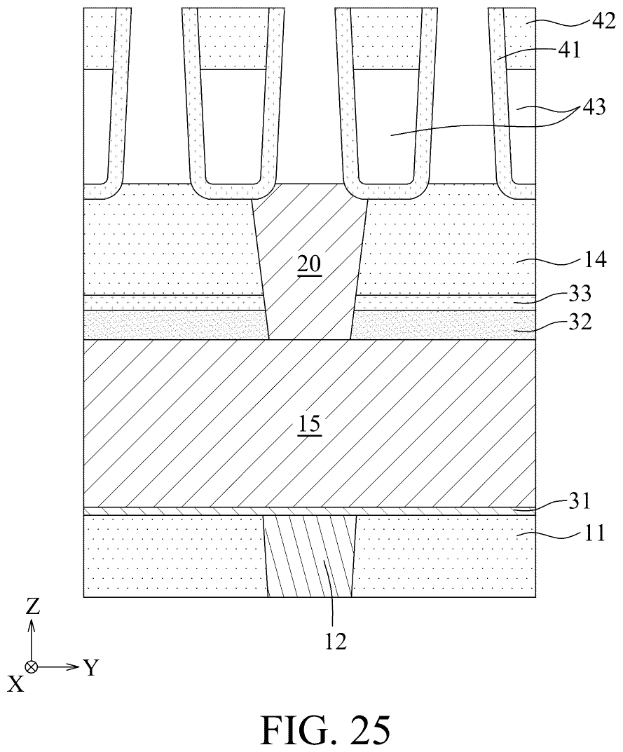

Referring to FIGS. 16 and 25, in step S17, the sacrificial hardmask layer 45 and the etch stop layer 18 (see FIG. 24) among the segments of the cap layer 41 are removed to form a plurality of metal line recesses, one of which exposes the metal via 20. In accordance with some embodiments, the removal of the sacrificial hardmask layer 45 may be performed using, for example, a dry plasma process, a wet clean process, other suitable processes, or any combination thereof. In accordance with some embodiments, the removal of the etch stop layer 18 may be performed using, for example, a dry plasma process, a wet clean process, other suitable processes, or any combination thereof.

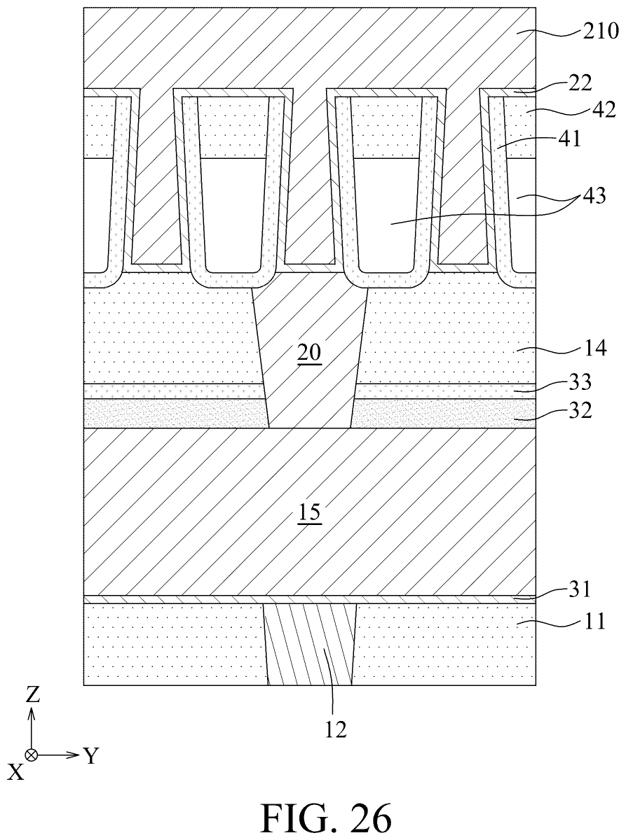

Referring to FIGS. 16 and 26, in step S18, a conductive barrier layer 22 is conformally deposited on the dielectric layer 42, the cap layer 41 and the ILD 14, and a metalization process is performed to fill metal line recesses with metal. In the illustrative embodiment, the metallization process is a damascene process including deposition of a metal layer 210. In accordance with some embodiments, the conductive barrier layer 22 may include, for example, TaN, TiN, other suitable materials, or any combination thereof. In accordance with some embodiments, the metal layer 210 may include, for example, Cu, W, Mo, Co, Ru, other suitable conductive materials, or any combination thereof.

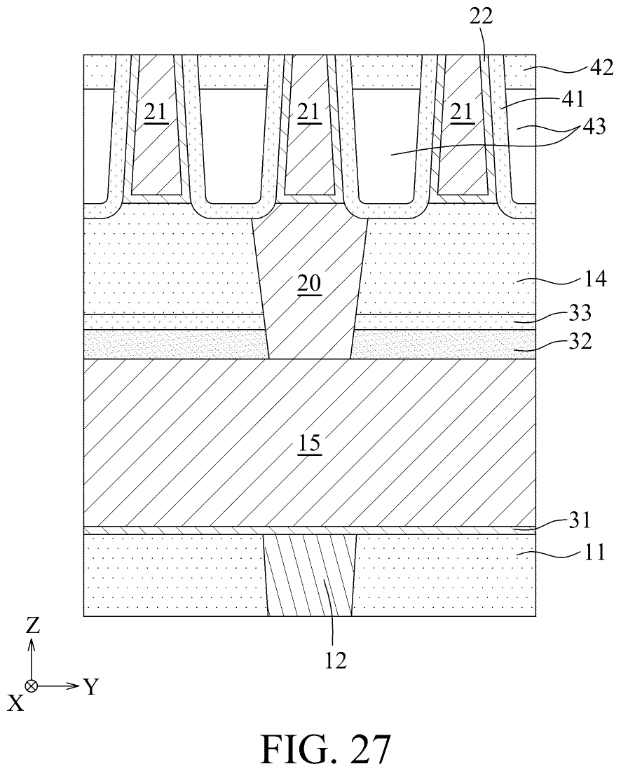

Referring to FIGS. 16 and 27, in step S19, a CMP process is performed to remove an excessive part of the metal layer 210 and a part of the conductive barrier layer 22, thereby forming separated metal lines 21 and exposing the remaining parts of the dielectric layer 42 that seal the air gaps 43. Then, in step S20, an etch stop layer 44 is deposited over the metal lines 21 and the dielectric layer 42, forming the structure as shown in FIGS. 14 and 15.

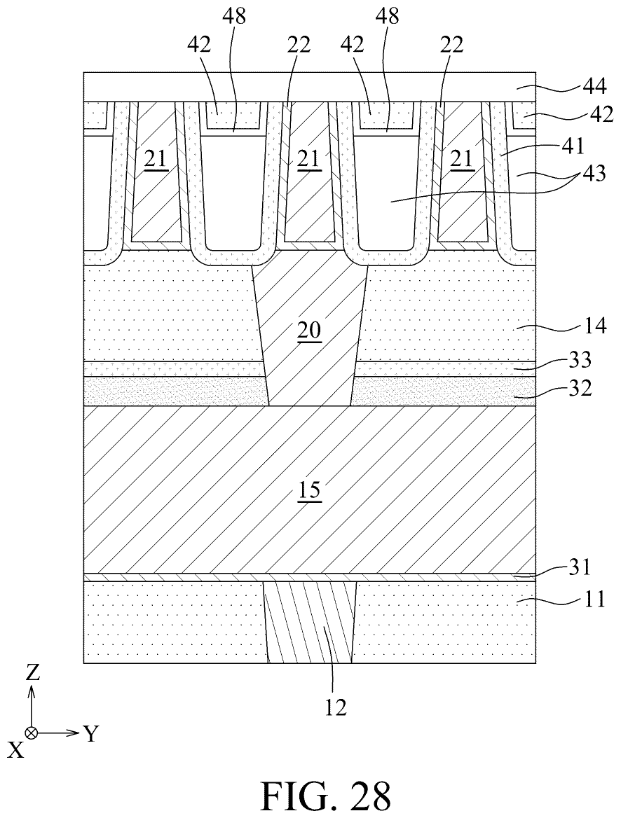

Referring to FIGS. 14 and 28, an X-cut view and a Y-cut view of an interconnection structure are illustrated in accordance with a fourth embodiment, which is similar to the second embodiment. In the fourth embodiment, each of the air gaps 43 is covered by a sustaining layer 48, and the dielectric layer 42 is disposed over the sustaining layer 48. The sustaining layer 48 is divided into a plurality of segments each being disposed in between adjacent metal lines 21 in the Y-axis direction, and is disposed between one of the air gaps 43 and a corresponding part of the dielectric layer 42. In particular, each segment of the sustaining layer 48 has a U-shaped cross section and is uniform in thickness. Each U-shaped segment of the sustaining layer 48 has a first portion and a second portion that respectively extend in parallel to opposing sidewalls respectively of the adjacent metal lines 21, and a third segment that interconnects lower ends of the first and second parts.

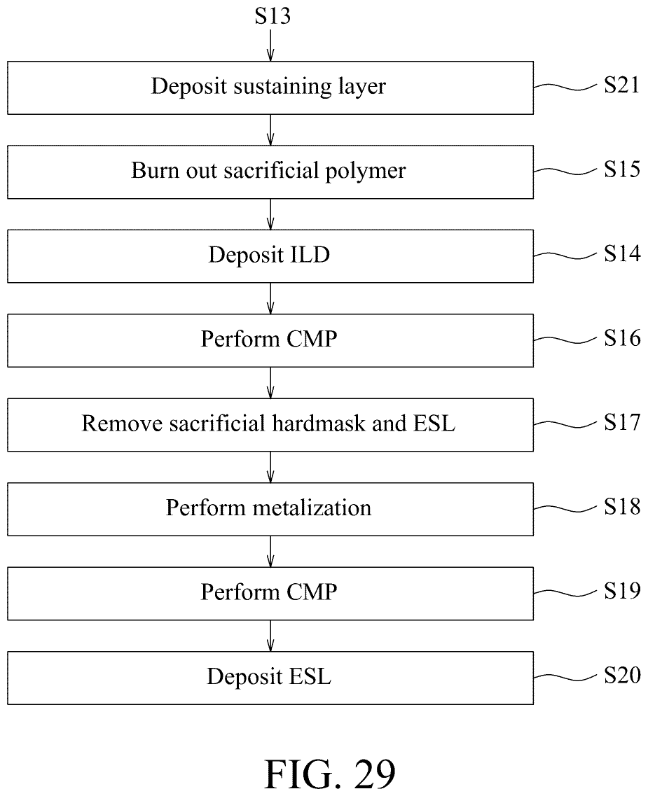

FIG. 29 is a flow chart illustrating some steps of a method for fabricating an interconnection structure in accordance with the fourth embodiment. Particularly, the method according to the fourth embodiment is similar to the method according to the third embodiment as shown in FIG. 16, and differs in that the method according to the fourth embodiment further includes a step S21 following step S13 in the method according to the third embodiment, and the order of steps S14 and S15 is switched.

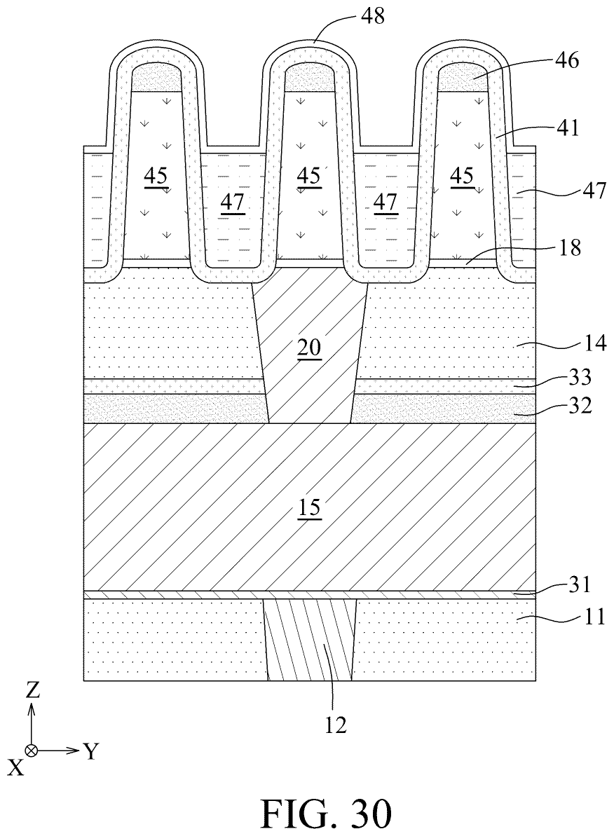

Referring to FIGS. 29 and 30, in step S21, a sustaining layer 48 is conformally deposited over the over the cap layer 41, the sacrificial polymer features 47 and the dummy line stacks. In accordance with some embodiments, the sustaining layer 48 may include, for example, elements such as Si, O, C, N, other suitable elements, or any combination thereof (e.g., SiO, SiOC, SiCN, SiON, SiN, SiOCN, etc.), and may be formed using, for example, ALD, PEALD, other suitable deposition techniques, or any combination thereof.

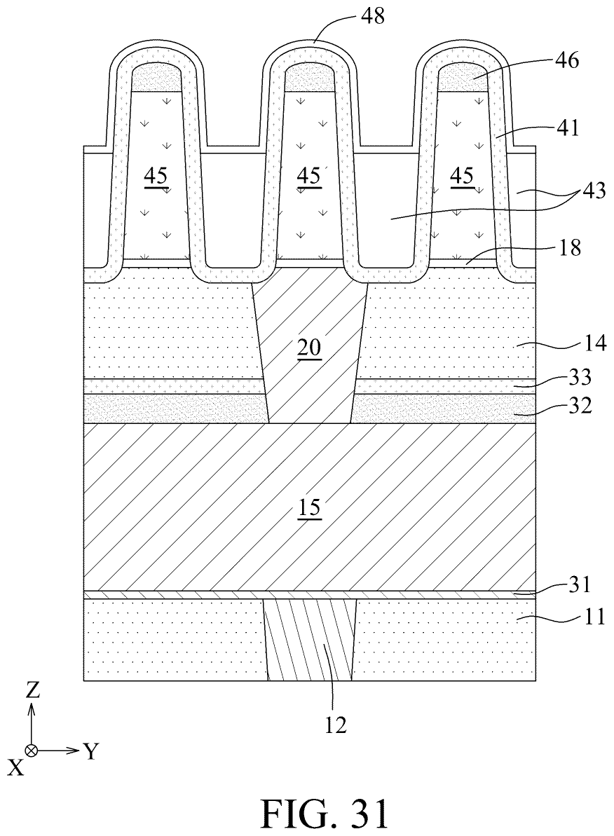

Referring to FIGS. 29 and 31, in step S15 that follows step S21, the sacrificial polymer features 47 (see FIG. 30) are burnt out using, for example, a thermal process, a UV process, other suitable techniques, or any combination thereof, while the sustaining layer 48 remains. As a result, a plurality of air gaps (or voids) 43 are formed among the dummy line stacks and under the sustaining layer 48. In order to facilitate the outgassing and complete removal of the decomposed sacrificial polymer features 47 during the burning out process, the sustaining layer 48 may be permeable or porous.

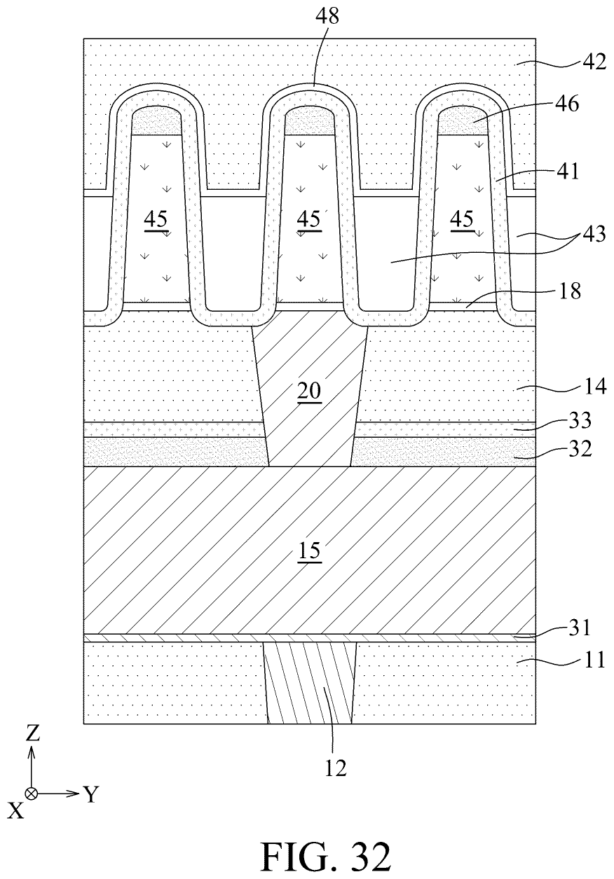

Referring to FIGS. 29 and 32, in step S14 that follows step S15, a dielectric layer 42 is deposited over the sustaining layer 48. In accordance with some embodiments, the sustaining layer 48 formed in step S21 may have a thickness in a range from about 5 angstroms to about 30 angstroms, thereby having a sufficient strength to support the dielectric layer 41 after the removal of the sacrificial polymer features 47 (see FIG. 30). In this embodiment, since the sacrificial polymer features 47 (see FIG. 30) have been removed prior to the deposition of the dielectric layer 42, the dielectric layer 42 can have either a porous structure or a dense structure. In some variations of the fourth embodiment, step S14 may be performed before step S15 and after step S21. In other words, the dielectric layer 42 may be deposited over the sustaining layer 48 before removal of the sacrificial polymer features 47, and the dielectric layer 42 would be formed to be porous to facilitate the subsequent burning out of the sacrificial polymer features 47 in step S15.

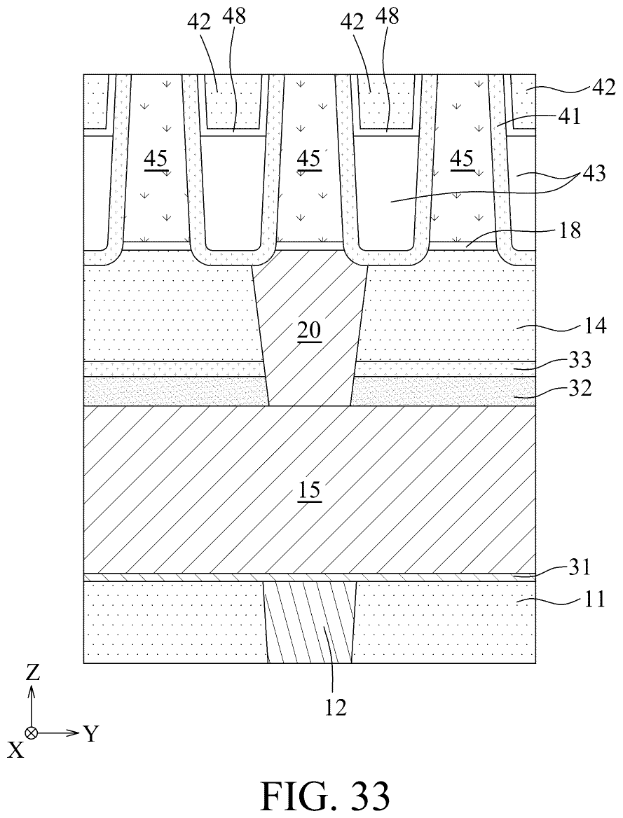

Referring to FIGS. 29 and 33, in step S16, a CMP process is performed to remove an upper part of the dielectric layer 42, an upper part of the sustaining layer 48, an upper part of the cap layer 41, and the hardmask layer 46, thereby exposing the patterned sacrificial hardmask layer 45 that has been formed to include a plurality of hardmask lines. The CMP process divides the dielectric layer 42 into multiple parts, divides the sustaining layer 48 into multiple separate segments that respectively support and load the multiple parts of the dielectric layer 42, and divides the cap layer 41 into multiple separate segments.

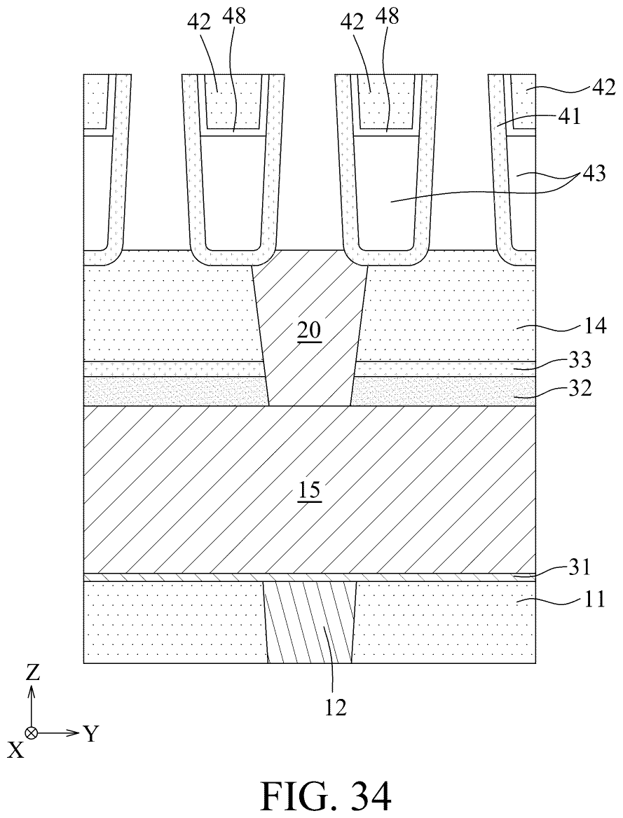

Referring to FIGS. 29 and 34, in step S17, the sacrificial hardmask layer 45 and the etch stop layer 18 (see FIG. 33) are removed, thereby forming a plurality of metal line recesses among the segments of the cap layer 41, and exposing the metal via 20 in one of the metal line recesses.

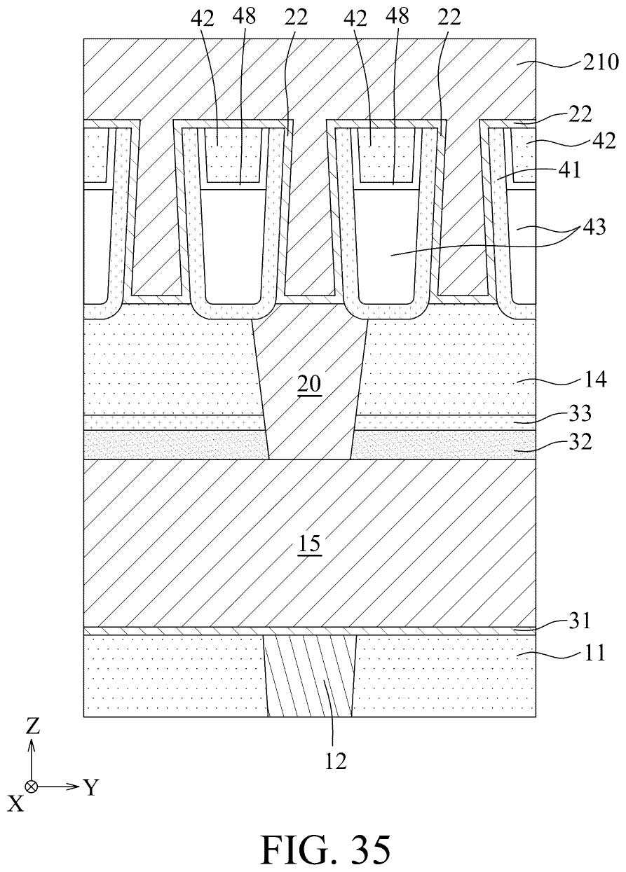

Referring to FIGS. 29 and 35, in step S18, a conductive barrier layer 21 is conformally deposited, and a metallization process is performed to fill the metal line recesses among the segments of the cap layer 41 with a metal layer 210.

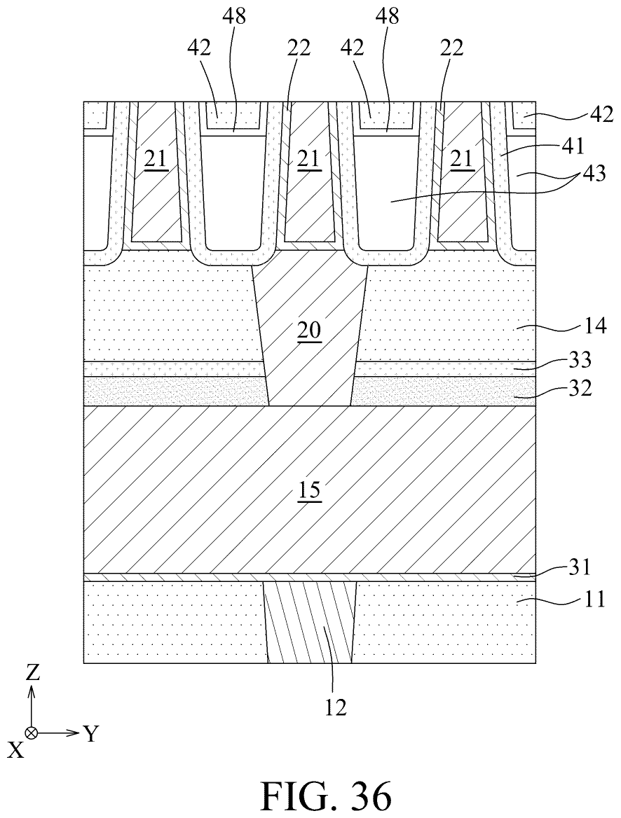

Referring to FIGS. 29 and 36, in step S19, a CMP process is performed to remove an excessive part of the metal layer 210 and a part of the conductive barrier layer 22, thereby forming separated metal lines 21 and exposing the remaining parts of the dielectric layer 42 that seal the air gaps 43. Then, in step S20, an etch stop layer 44 is deposited over the metal lines 21 and the dielectric layer 42, forming the structure as shown in FIGS. 14 and 28.

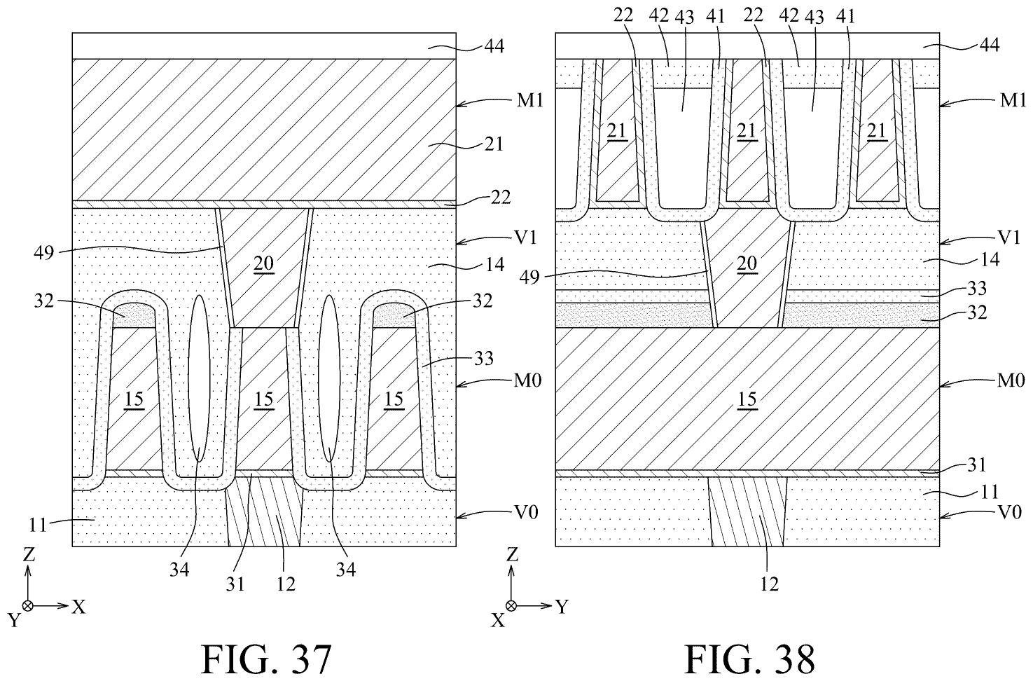

FIGS. 37 and 38 respectively illustrate an X-cut view and a Y-cut view of an interconnection structure in accordance with a fifth embodiment, which is similar to the third embodiment. In the fifth embodiment, a dielectric barrier layer 49 is formed between sidewalls of the metal via 20 and the ILD 14 for preventing metal atoms in the metal via 20 from diffusing into adjacent layers, such as the ILD 14, and/or for enhancing adhesion of the metal via 20. It is noted that the dielectric barrier layer 49 is not formed between a bottom of the metal via 20 and the underlying metal line 15, so the metal via 20 is directly connected to and in contact with the metal line 15, thereby maintaining low resistance.

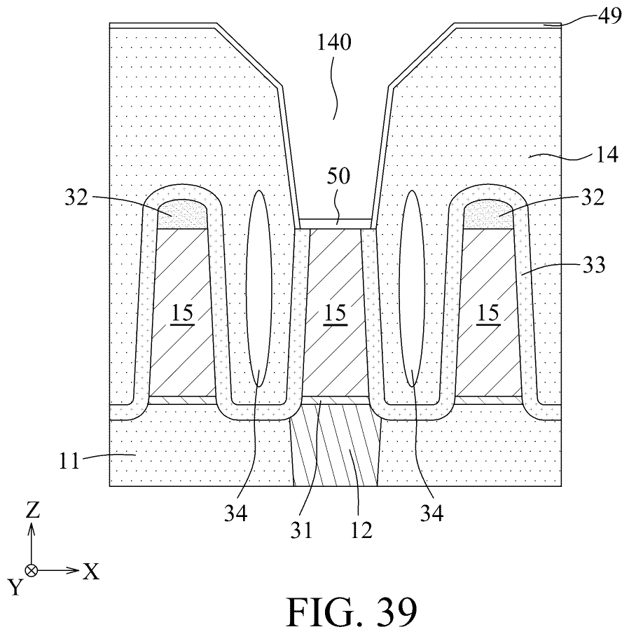

A method for fabricating an interconnection structure in accordance with the fifth embodiment is similar to the method according to the third embodiment, which includes steps S01 to S07 as shown in FIG. 3 and steps S10 to S20 as shown in FIG. 16. However, in the method according to the fifth embodiment, as illustrated in FIG. 39, after patterning the ILD 14 in step S05, an inhibitor film 50 is deposited on top of the exposed metal line 15 in the via hole 140, and a dielectric barrier layer 49 is conformally deposited over the ILD 14. In accordance with some embodiments, the inhibitor film 50 may be a self-assembled monolayer that includes, for example, thiols, n-octadecylphosphonic acid (ODPA), other suitable materials (e.g., silane-based materials including elements such as Si, O, C, N, other suitable elements, or any combination thereof), or any combination thereof, and may be formed using, for example, molecular layer deposition (MLD), CVD, ALD, spin-on, other suitable techniques, or any combination thereof. In accordance with some embodiments, the dielectric barrier layer 49 may include, for example, elements such as Si, O, C, N, Al, other suitable materials, or any combination thereof (e.g., SiOC, AlOx, AlON, AlN, SiOCN, SiN, SiCN, etc.), and may be formed using, for example, CVD, ALD, other suitable techniques, or any combination thereof. The material of the inhibitor film 50 is characterized by its tendency to form on the metal line 15 rather than on the ILD 14, and its ability of inhibiting or restraining the dielectric barrier layer 49 from growing on the inhibitor film 50.

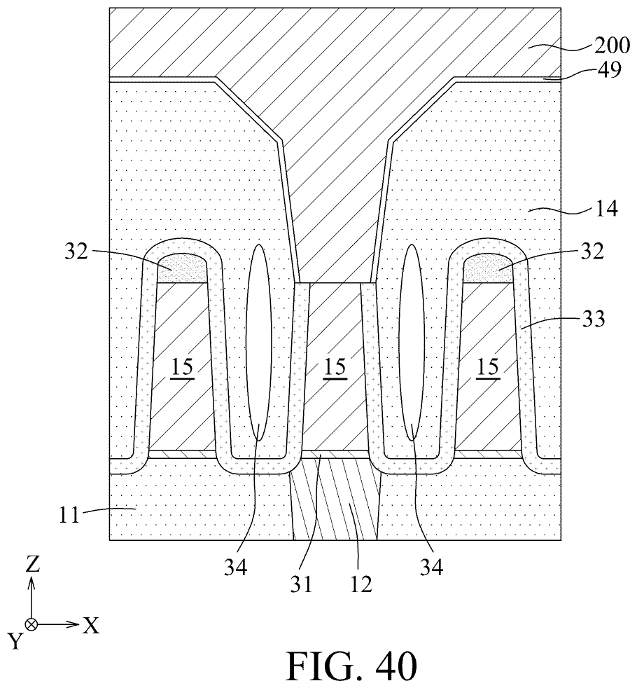

Referring to FIGS. 3 and 40, in step S06, the inhibitor film 50 (see FIG. 39) is removed to expose the underlying metal line 15, and a metal layer 200 is deposited to fill the via hole 140 (see FIG. 39) and over the metal line 15 and the dielectric barrier layer 49. In accordance with some embodiments, the removal of the inhibitor film 50 may include, for example, a UV process, a plasma treatment, other suitable techniques, or any combination thereof. Then, a CMP process is performed in step S07 to remove excessive portions of the metal layer 200

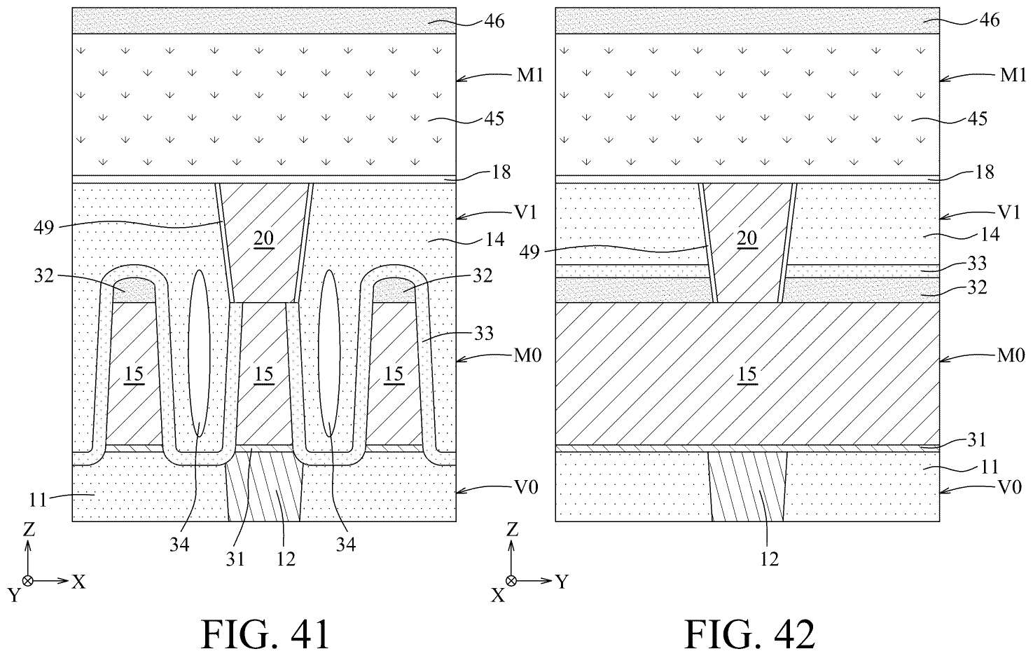

Referring to FIGS. 16, 41 and 42, in step S10, an etch stop layer 18, a sacrificial hardmask layer 45 and a hardmask layer 46 are deposited over the ILD 14 and the metal via 20 that was formed by the CMP process in step S07, where FIG. 41 is an X-cut view and FIG. 42 is a Y-cut view.

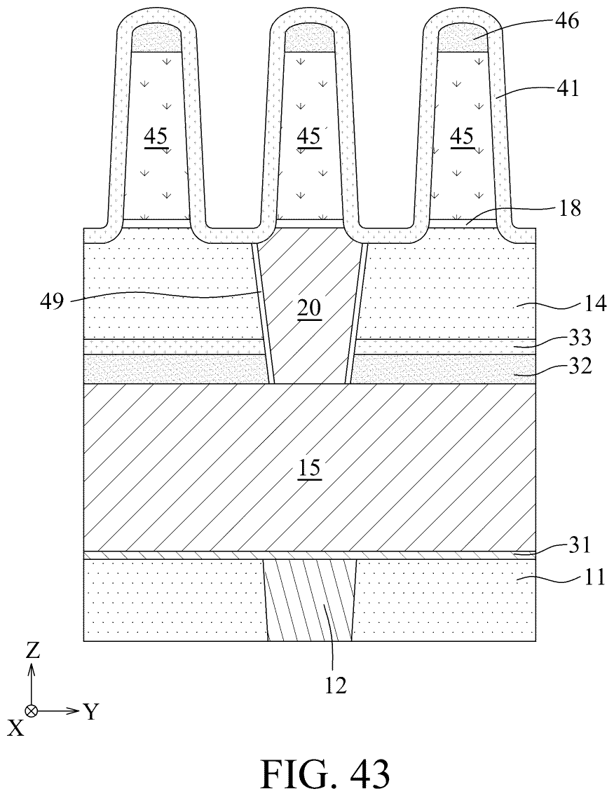

Referring to FIGS. 16 and 43, in step S11, the hardmask layer 46, the sacrificial hardmask layer 45 and the etch stop layer 18 are patterned and etched, thereby forming a plurality of dummy line stacks. Then, a cap layer 41 is conformally deposited on the dummy line stacks.

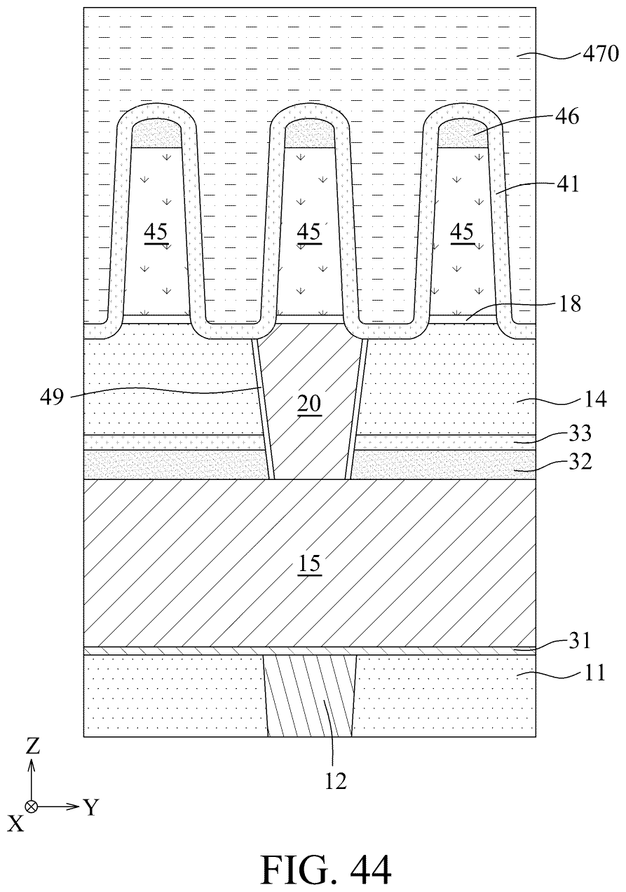

Referring to FIGS. 16 and 44, in step S12, a sacrificial polymer layer 470 is deposited over the cap layer 41 and filled in between the dummy line stacks.

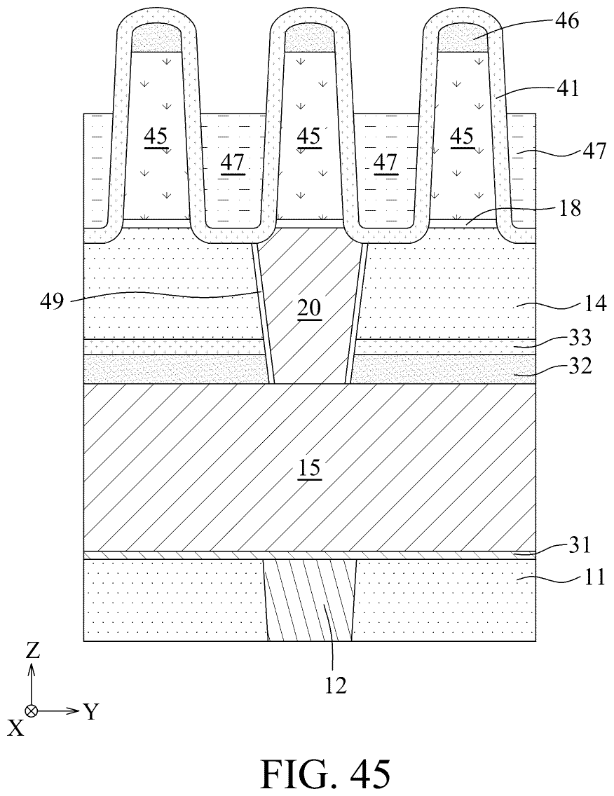

Referring to FIGS. 16 and 45, in step S13, an ashing back process is performed, thereby forming a plurality of sacrificial polymer features 47 among the dummy line stacks.

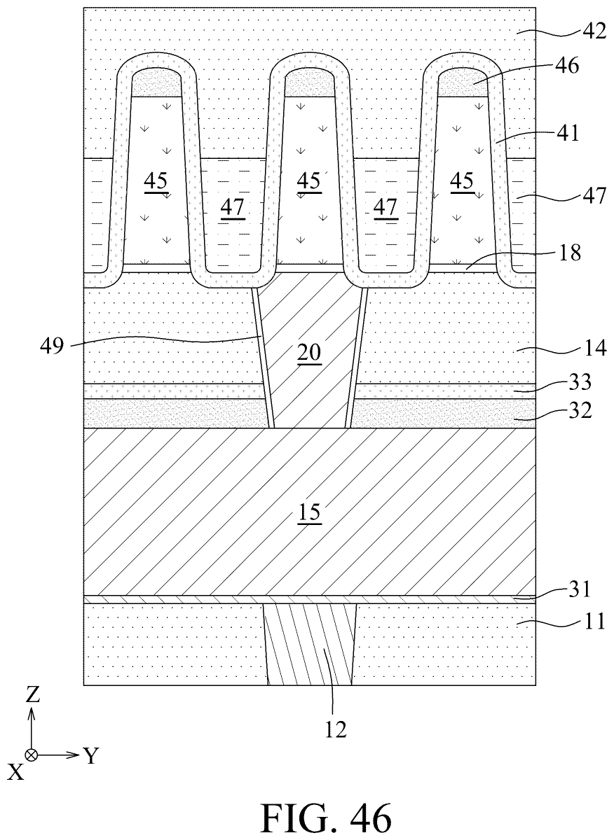

Referring to FIGS. 16 and 46, in step S14, a dielectric layer 42 is deposited over the cap layer 41, the sacrificial polymer features 47 and the dummy line stacks.

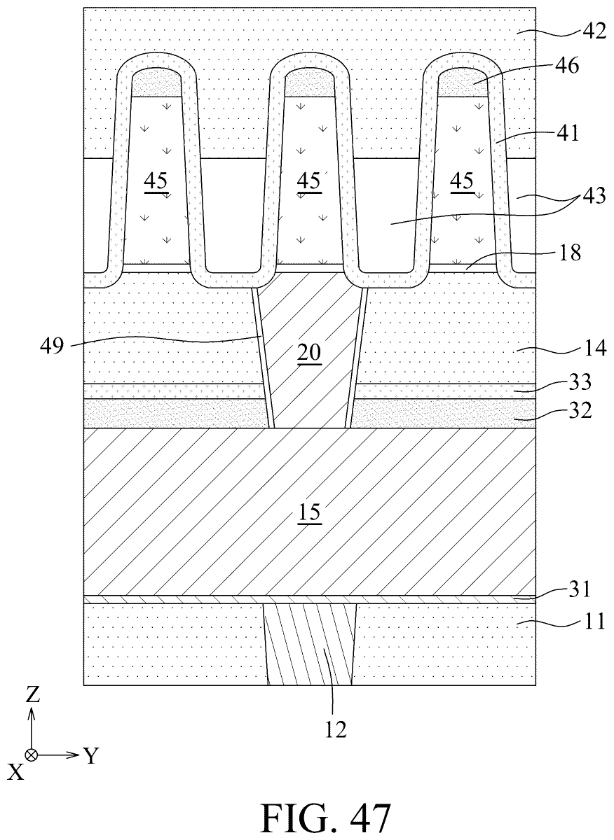

Referring to FIGS. 16 and 47, in step S15, the sacrificial polymer features 47 (see FIG. 46) are removed, while the dielectric layer 42 remains. As a result, a plurality of air gaps (or voids) 43 are formed among the dummy line stacks and under the dielectric layer 42.

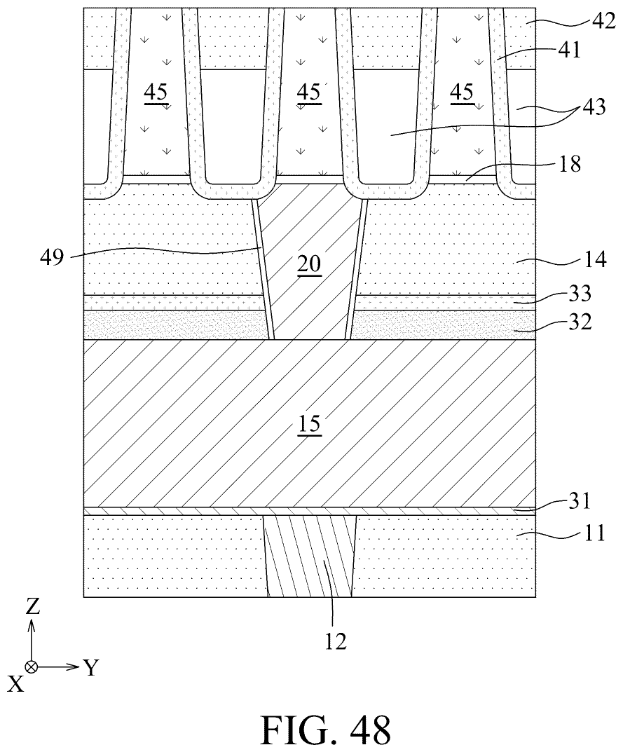

Referring to FIGS. 16 and 48, in step S16, a CMP process is performed to remove an upper part of the dielectric layer 42, an upper part of the cap layer 41, and the hardmask layer 46, thereby exposing the patterned sacrificial hardmask layer 45. The CMP process divides the dielectric layer 42 into multiple separate parts that respectively cover and preserve the air gaps 43, and divides the cap layer 41 into multiple separate segments.

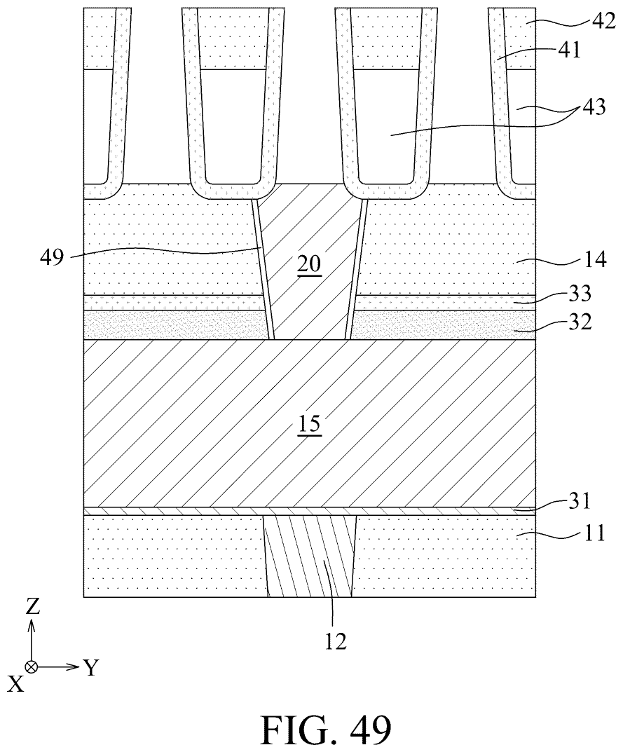

Referring to FIGS. 16 and 49, in step S17, the sacrificial hardmask layer 45 and the etch stop layer are removed to form a plurality of metal line recesses, one of which exposes the metal via 20.

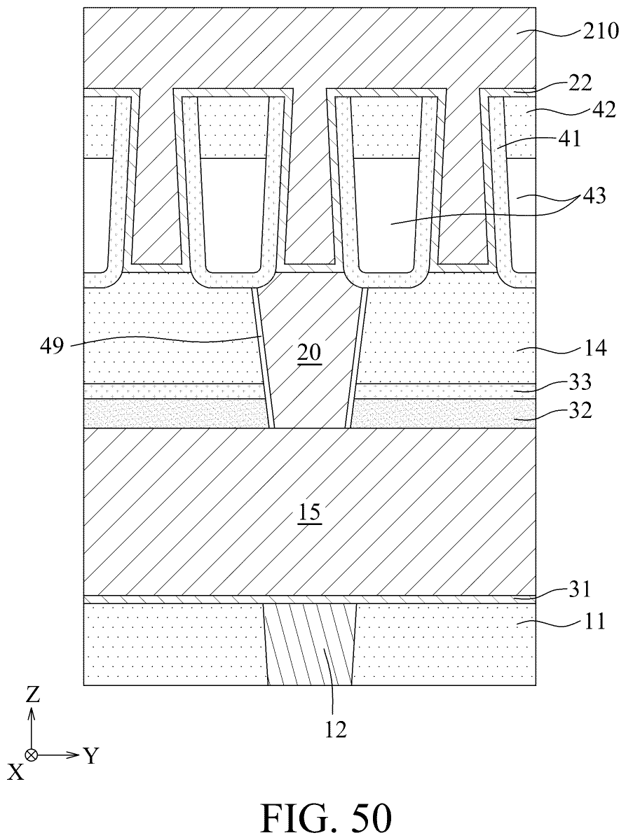

Referring to FIGS. 16 and 50, in step S18, a conductive barrier layer 22 is conformally deposited, and a metallization process is performed to fill the metal line recesses among the segments of the cap layer 41 with a metal layer 210.

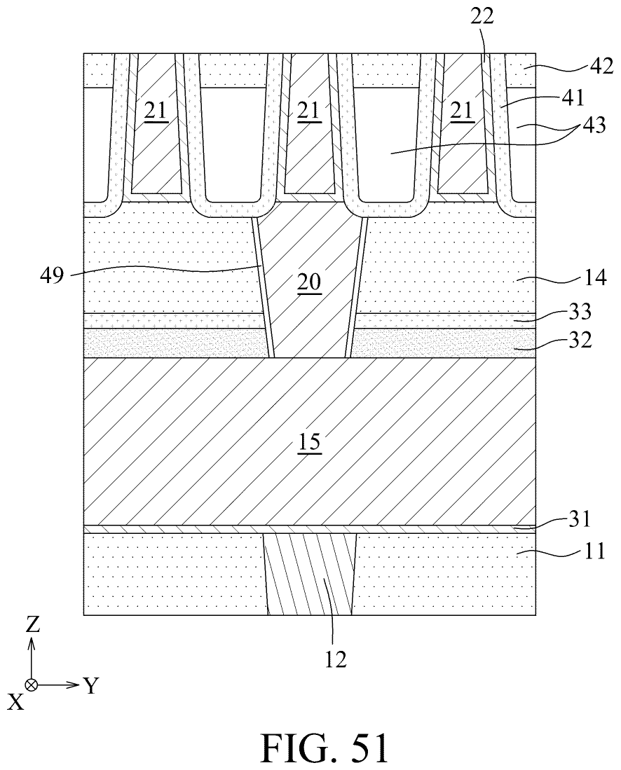

Referring to FIGS. 16 and 51, in step S19, a CMP process is performed to remove an excessive part of the metal layer 210 and a part of the conductive barrier layer 22, thereby forming separated metal lines 21 and exposing the remaining parts of the dielectric layer 42 that seal the air gaps 43. Then, in step S20, an etch stop layer 44 is deposited over the metal lines 21 and the dielectric layer 42, forming the structure as shown in FIGS. 37 and 38.

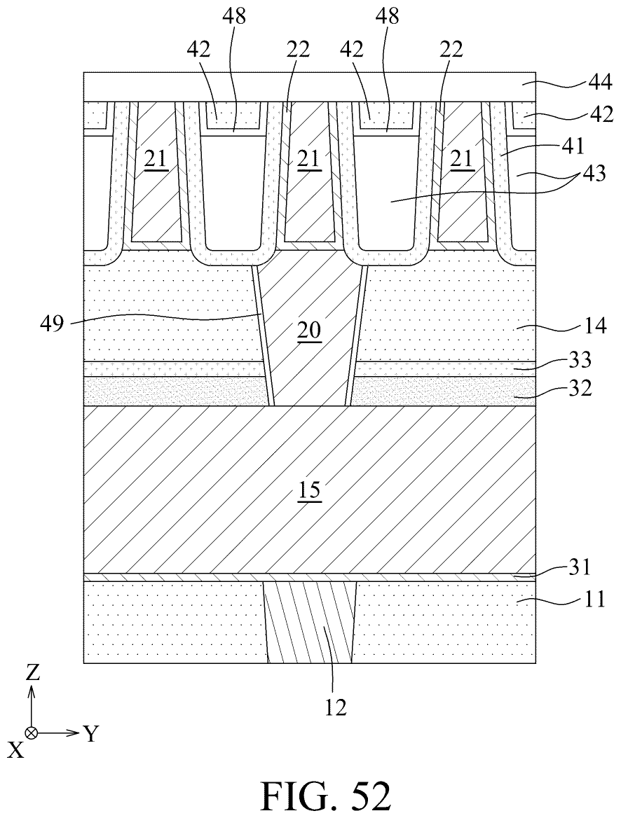

Referring to FIGS. 37 and 52, an X-cut view and a Y-cut view of an interconnection structure are illustrated in accordance with a sixth embodiment, which is similar to the fifth embodiment. In the sixth embodiment, each of the air gaps 43 is covered by a sustaining layer 48, and the dielectric layer 42 is disposed over the sustaining layer 48. The process of forming the sustaining layer 48 is similar to that described for the fourth embodiment (e.g., the steps illustrated in FIG. 29), so details thereof are not repeated herein for the sake of brevity.

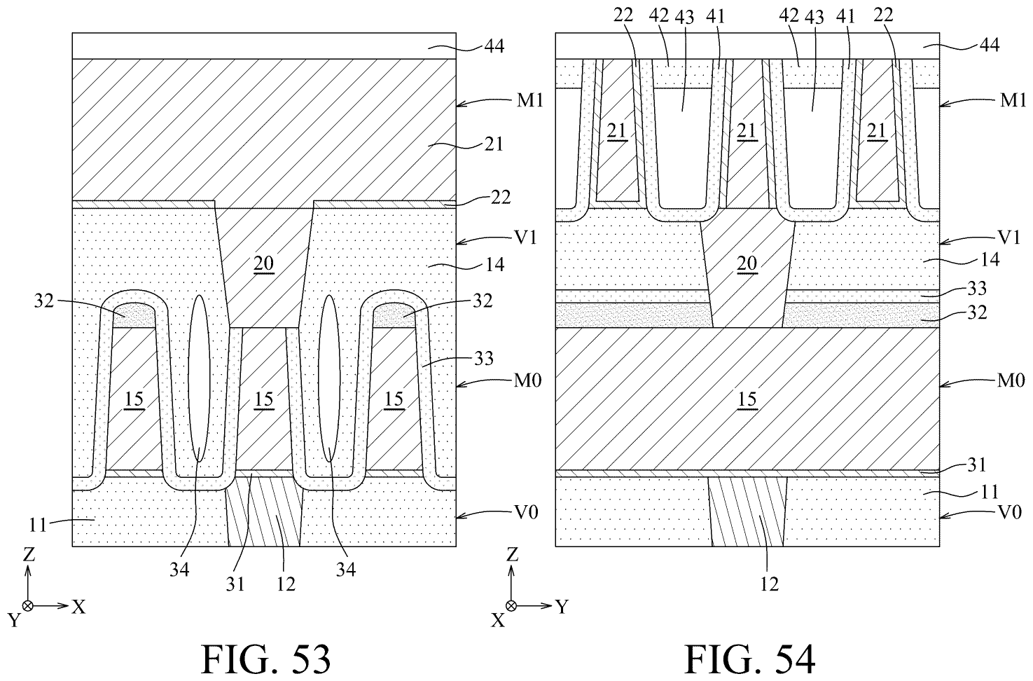

FIGS. 53 and 54 respectively illustrate an X-cut view and a Y-cut view of an interconnection structure in accordance with a seventh embodiment, which is similar to the third embodiment. In the seventh embodiment, the metal via 20 directly contacts the overlying metal line 21, without a conductive barrier layer 22 interposed therebetween. Since the conductive barrier layer 22 usually has a higher resistivity than the metal line 21, this structure may achieve lower overall resistance for the connection between the metal line 21 and the metal via 20.

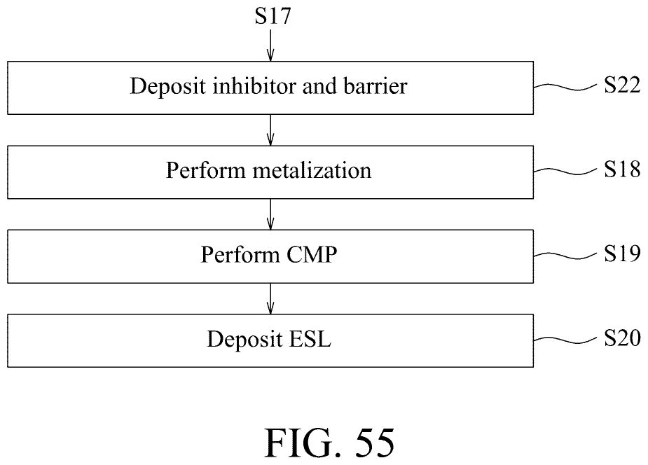

A method for fabricating an interconnection structure in accordance with the seventh embodiment is similar to the method according to the third embodiment, and includes steps S01 to S07 as shown in FIG. 3, steps S10 to S17 as shown in FIG. 16, and, as shown in FIG. 55, step S22 following step S17, and steps S18 to S20 following step S22. Details of steps S01 to S07 and steps S10 to S17 are not repeated herein for the sake of brevity.

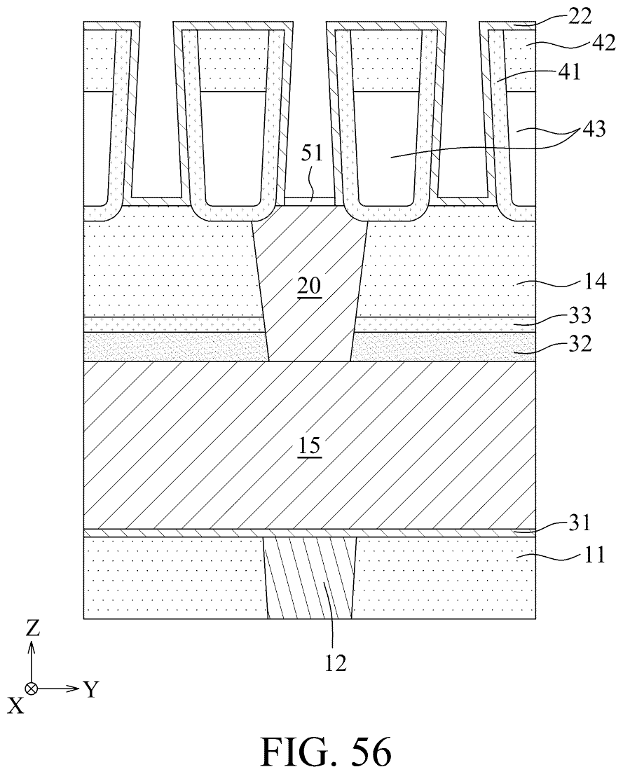

Referring to FIGS. 55 and 56, in step S22, an inhibitor film 51 is deposited on top of a part of the metal via 20 that is exposed between adjacent two segments of the cap layer 41, and a conductive barrier layer 22 is conformally deposited on the dielectric layer 42, the ILD 14 and the cap layer 41, but not on the inhibitor film 51. In accordance with some embodiments, the inhibitor film 51 may be a self-assembled monolayer that includes, for example, thiols, n-octadecylphosphonic acid (ODPA), other suitable materials (e.g., silane-based materials including elements such as Si, O, C, N, other suitable elements, or any combination thereof), or any combination thereof, and may be formed using, for example, molecular layer deposition (MLD), CVD, ALD, spin-on, other suitable techniques, or any combination thereof. The material used in the inhibitor film 51 is able to inhibit or restrain growth of the conductive barrier layer 22 as well, which usually includes TiN, TaN, etc.

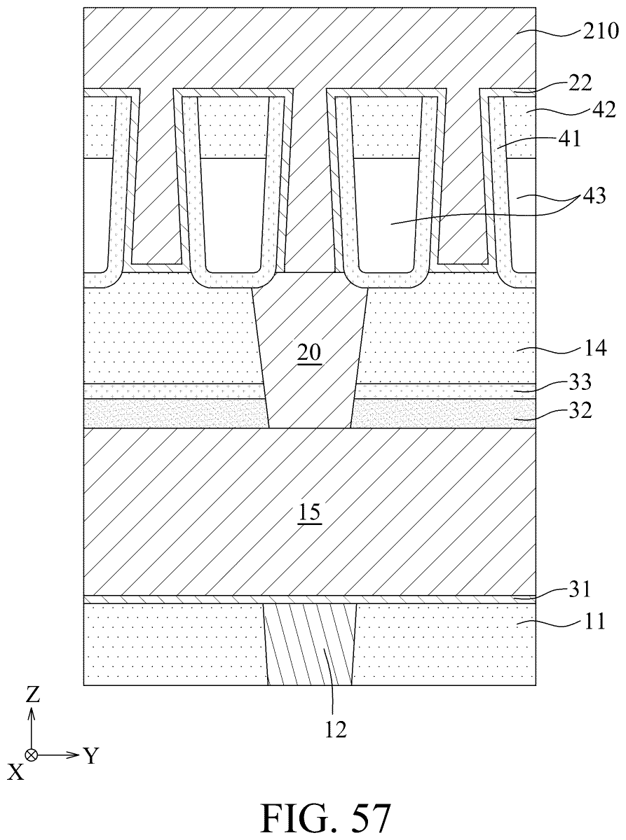

Referring to FIGS. 55 and 57, in step S18, the inhibitor film 51 is removed to expose the metal via 20, and a metallization process is performed to fill the recesses among the segments of the cap layer 41 with a metal layer 210, so the metal layer 210 directly contacts the metal via 20, without having the conductive barrier layer 22 interposed therebetween.

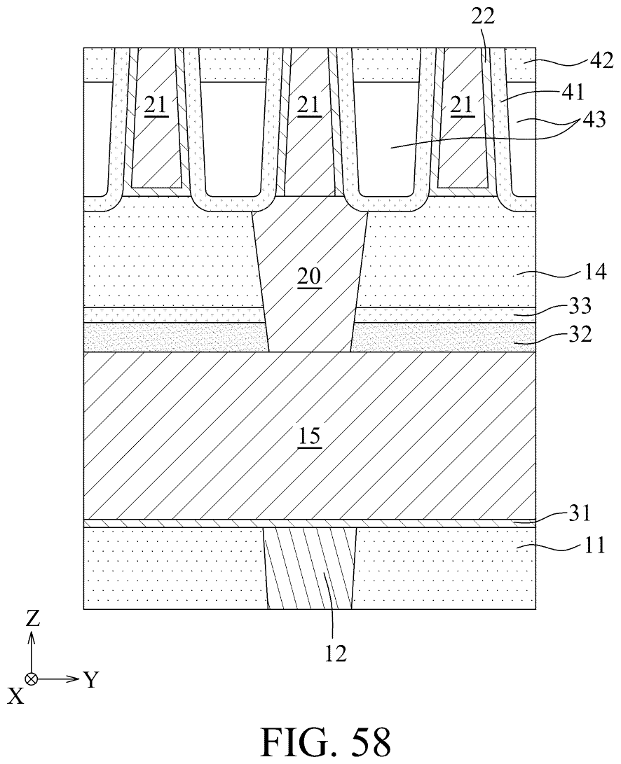

Referring to FIGS. 55 and 58, in step S19, a CMP process is performed to remove an excessive part of the metal layer 210 and a part of the conductive barrier layer 22, thereby forming separated metal lines 21 and exposing the remaining parts of the dielectric layer 42 that seal the air gaps 43. Then, in step S20, an etch stop layer 44 is deposited over the metal lines 21 and the dielectric layer 42, forming the structure as shown in FIGS. 53 and 54.

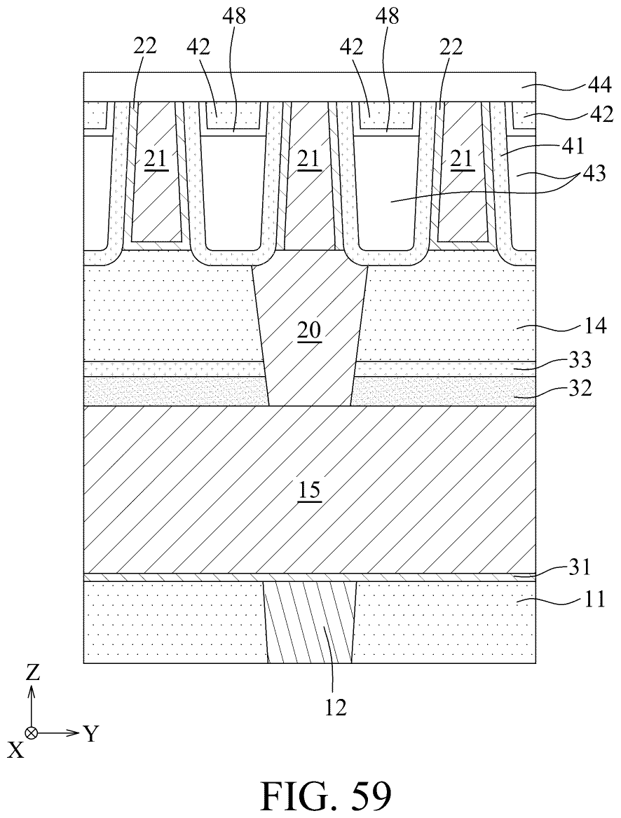

Referring to FIGS. 53 and 59, an X-cut view and a Y-cut view of an interconnection structure are illustrated in accordance with an eighth embodiment, which is similar to the seventh embodiment. In the eighth embodiment, each of the air gaps 43 is covered by a sustaining layer 48, and the dielectric layer 42 is disposed over the sustaining layer 48. The process of forming the sustaining layer 48 is similar to that described for the fourth embodiment (e.g., the steps illustrated in FIG. 29), so details thereof are not repeated herein for the sake of brevity.

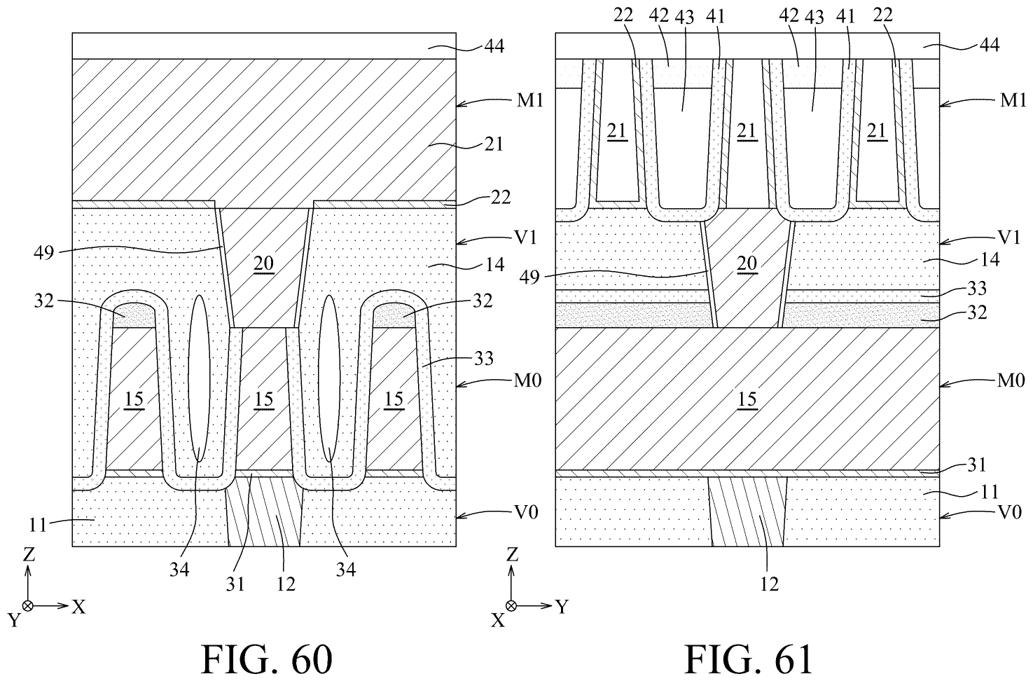

FIGS. 60 and 61 respectively illustrate an X-cut view and a Y-cut view of an interconnection structure in accordance with a ninth embodiment, which is similar to the fifth embodiment. In the ninth embodiment, the metal via 20 directly contacts the overlying metal line 21, without a conductive barrier layer 22 interposed therebetween. The process of forming a conductive barrier layer 22 that is not interposed between the metal via 20 and the metal line 21 has been described for the seventh embodiment, so the details thereof are not repeated herein for the sake of brevity. In other words, the ninth embodiment can be deemed as a combination of the fifth embodiment and the seventh embodiment.

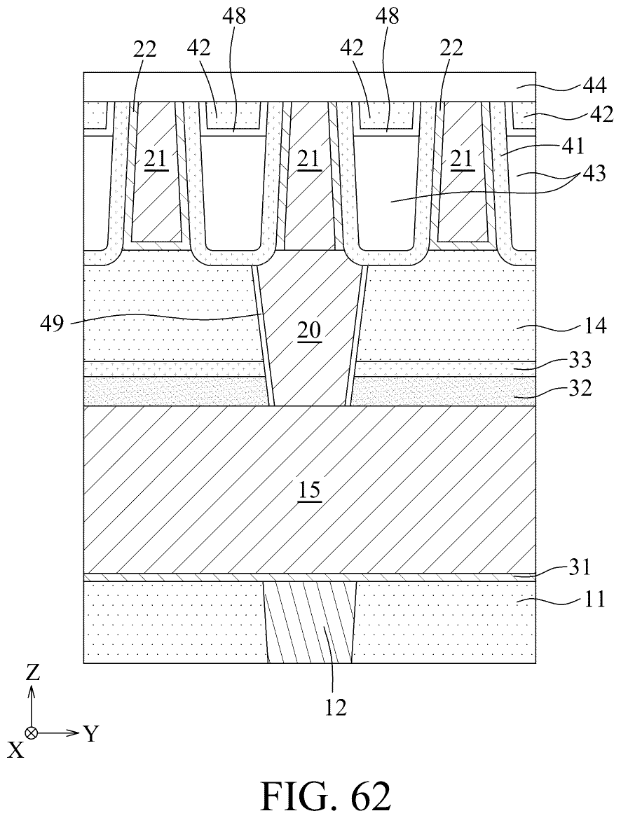

Referring to FIGS. 60 and 62, an X-cut view and a Y-cut view of an interconnection structure are illustrated in accordance with a tenth embodiment, which is similar to the ninth embodiment. In the tenth embodiment, each of the air gaps 43 is covered by a sustaining layer 48, and the dielectric layer 42 is disposed over the sustaining layer 48. The process of forming the sustaining layer 48 is similar to that described for the fourth embodiment (e.g., the steps illustrated in FIG. 29), so details thereof are not repeated herein for the sake of brevity.

In accordance with some embodiments, a method for fabricating an interconnection structure is provided. In one step, a first metal layer is formed over a semiconductor substrate. In one step, the first metal layer is patterned to form a first metal line and a second metal line. In one step, a first ILD layer is deposited over the first metal line and the second metal line, where the first ILD layer has a first air gap disposed between the first metal line and the second metal line. In one step, a via hole is formed in the first ILD layer, where the via hole exposes the first metal line. In one step, a metal via is formed in the via hole.

In accordance with some embodiments, an upper portion of the first air gap is narrower than an intermediate portion of the first air gap.

In accordance with some embodiments, the first ILD layer is deposited in a non-conformal manner, thereby forming the first air gap.

In accordance with some embodiments, in one step, a third metal line and a fourth metal line are formed over the first ILD layer using a damascene process. The third metal line is disposed over and connected to the metal via, and the third metal line is spaced apart from the fourth metal line by a second air gap and a second ILD layer.

In accordance with some embodiments, a top portion of the second air gap is wider than a bottom portion of the second air gap.

In accordance with some embodiments, the second ILD layer and the second air gap are formed before forming the third metal line and the fourth metal line. The second air gap is covered by the second ILD layer.

In accordance with some embodiments, the forming of the second ILD layer and the second air gap includes some sub-steps. In one sub-step, a sacrificial hardmask layer is formed over the first ILD layer and the metal via. In one sub-step, the sacrificial hardmask layer is patterned to form a first sacrificial hardmask feature and a second sacrificial hardmask feature, where the first sacrificial hardmask feature is disposed over and connected to the metal via. In one sub-step, a sacrificial polymer feature is formed between the first sacrificial hardmask feature and the second sacrificial hardmask feature. In one sub-step, a porous layer is formed over the sacrificial polymer feature. In one sub-step, the sacrificial polymer feature that is disposed under the porous layer is burnt out, thereby forming the second air gap below the porous layer.

In accordance with some embodiments, the porous layer is the second ILD layer that is non-conformally deposited over the sacrificial hardmask layer and the sacrificial polymer feature.

In accordance with some embodiments, the porous layer is a sustaining layer that is conformally deposited over the sacrificial hardmask layer and the sacrificial polymer feature, and in one step, after burning out the sacrificial polymer feature, depositing the second ILD layer over the sustaining layer.

In accordance with some embodiments, the forming of the third metal line and the fourth metal line includes some sub-steps. In one sub-step, the first sacrificial hardmask feature and the second sacrificial hardmask feature are removed, thereby forming a first metal line recess and a second metal line recess, where the first metal line recess exposes the metal via. In one sub-step, the third metal line and the fourth metal line are formed in the first metal line recess and the second metal line recess, respectively.

In accordance with some embodiments, the method includes some steps before forming the third metal line and the fourth metal line. In one of those steps, an inhibitor film is deposited on top of the metal via. In one of those steps, a barrier film is conformally deposited over the first ILD layer, wherein the inhibitor film restrains the barrier film from growing on the inhibitor film. In one of those steps, the inhibitor film is removed. The barrier film is disposed between the first ILD layer and the fourth metal line, and is absent between the metal via and the third metal line.

In accordance with some embodiments, the method includes some steps before forming the metal via. In one of those steps, an inhibitor film is deposited at the bottom of the via hole and over the first metal line. In one of those steps, a dielectric barrier film is conformally deposited over sidewalls of the via hole, wherein the inhibitor film restrains the dielectric barrier film from growing on the inhibitor film. In one of those steps, the inhibitor film is removed. The dielectric barrier film is disposed between the first ILD and the metal via, and is absent between the first metal line and the metal via.

In accordance with some embodiments, a method for fabricating an interconnection structure is provided. In one step, a first metal line and a second metal line are formed over a via layer that includes a first metal via directly connected to a transistor. The first metal line is disposed over and connected to the first metal via. In one step, a first ILD layer is formed to have a first air gap disposed between the first metal line and the second metal line. In one step, a second metal via is formed in the first ILD layer. The second metal via is disposed over and connected to the first metal line. In one step, a third metal line and a fourth metal line are formed over the first ILD layer. The third metal line is disposed over and connected to the second metal via, and is spaced apart from the fourth metal line by a second ILD layer and a second air gap under the second ILD layer.

In accordance with some embodiments, the first air gap is taller than the first metal line and the second metal line, and the second air gap is shorter than the third metal line and the fourth metal line in height.

In accordance with some embodiments, a cross section of the first air gap has a curved upper edge, and a cross section of the second air gap has a straight upper edge.

In accordance with some embodiments, the first air gap is formed after forming the first metal line and the second metal line, and the second air gap is formed before forming the third metal line and the fourth metal line.

In accordance with some embodiments, the first air gap is formed during deposition of the first ILD layer, and the second air gap is formed after forming the second ILD layer.

In accordance with some embodiments, a sustaining layer is formed between the second ILD layer and the second air gap, the first air gap is formed during deposition of the first ILD layer, and the second air gap is formed after forming the sustaining layer and before forming the second ILD layer.

In accordance with some embodiments, an interconnection structure is provided to include a first ILD layer, a first metal line and a second metal line adjacent to each other and disposed in the first ILD layer, a metal via disposed in the first ILD layer, a second ILD layer disposed over the first ILD layer, and a third metal line and a fourth metal line adjacent to each other and disposed in the second ILD layer. The first ILD layer has a first air gap disposed between the first metal line and the second metal line. The metal via is disposed over and connected to the first metal line. The second ILD layer is disposed over the first ILD layer. The third metal line is disposed over and connected to the metal via, and is spaced apart from the fourth metal line by a second air gap under the second ILD layer.

In accordance with some embodiments, the first air gap has an oval cross section, and the second air gap has a polygonal cross section.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating an interconnection structure, comprising:
forming a first metal layer over a semiconductor substrate;
patterning the first metal layer to form a first metal line and a second metal line;
depositing a first interlayer dielectric (ILD) layer over the first metal line and the second metal line, where the first ILD layer has a first air gap disposed between the first metal line and the second metal line;
forming a via hole in the first ILD layer, where the via hole exposes the first metal line; and
forming a metal via in the via hole.

2. The method according to claim 1, wherein an upper portion of the first air gap is narrower than an intermediate portion of the first air gap.

3. The method according to claim 1, wherein the first ILD layer is deposited in a non-conformal manner, thereby forming the first air gap.

4. The method according to claim 1, further comprising:
forming a third metal line and a fourth metal line over the first ILD layer using a damascene process, wherein the third metal line is disposed over and connected to the metal via, and the third metal line is spaced apart from the fourth metal line by a second air gap and a second ILD layer.

5. The method according to claim 4, wherein a top portion of the second air gap is wider than a bottom portion of the second air gap.

6. The method according to claim 4, further comprising, before forming the third metal line and the fourth metal line: forming the second ILD layer and the second air gap, wherein the second air gap is covered by the second ILD layer.

7. The method according to claim 6, wherein the forming of the second ILD layer and the second air gap includes:
forming a sacrificial hardmask layer over the first ILD layer and the metal via;
patterning the sacrificial hardmask layer to form a first sacrificial hardmask feature and a second sacrificial hardmask feature, where the first sacrificial hardmask feature is disposed over and connected to the metal via;
forming a sacrificial polymer feature between the first sacrificial hardmask feature and the second sacrificial hardmask feature;
forming a porous layer over the sacrificial polymer feature; and
burning out the sacrificial polymer feature that is disposed under the porous layer, thereby forming the second air gap below the porous layer.

8. The method according to claim 7, wherein the porous layer is the second ILD layer that is non-conformally deposited over the sacrificial hardmask layer and the sacrificial polymer feature.

9. The method according to claim 7, wherein the porous layer is a sustaining layer that is conformally deposited over the sacrificial hardmask layer and the sacrificial polymer feature, and the method further comprises, after burning out the sacrificial polymer feature, depositing the second ILD layer over the sustaining layer.

10. The method according to claim 7, wherein the forming of the third metal line and the fourth metal line includes:
removing the first sacrificial hardmask feature and the second sacrificial hardmask feature, thereby forming a first metal line recess and a second metal line recess, where the first metal line recess exposes the metal via; and
forming the third metal line and the fourth metal line in the first metal line recess and the second metal line recess, respectively.

11. The method according to claim 4, further comprising, before forming the third metal line and the fourth metal line:
depositing an inhibitor film on top of the metal via;
conformally depositing a barrier film over the first ILD layer, wherein the inhibitor film restrains the barrier film from growing on the inhibitor film; and
removing the inhibitor film;
wherein the barrier film is disposed between the first ILD layer and the fourth metal line, and is absent between the metal via and the third metal line.

12. The method according to claim 1, further comprising, before forming the metal via:
depositing an inhibitor film at the bottom of the via hole and over the first metal line;
conformally depositing a dielectric barrier film over sidewalls of the via hole, wherein the inhibitor film restrains the dielectric barrier film from growing on the inhibitor film; and
removing the inhibitor film,
wherein the dielectric barrier film is disposed between the first ILD and the metal via, and is absent between the first metal line and the metal via.

13. A method for fabricating an interconnection structure, comprising:
forming a first metal line and a second metal line over a via layer that includes a first metal via directly connected to a transistor, wherein the first metal line is disposed over and connected to the first metal via;
forming a first interlayer dielectric (ILD) layer that has a first air gap disposed between the first metal line and the second metal line;
forming a second metal via in the first ILD layer, wherein the second metal via is disposed over and connected to the first metal line; and
forming a third metal line and a fourth metal line over the first ILD layer, wherein the third metal line is disposed over and connected to the second metal via, and is spaced apart from the fourth metal line by a second ILD layer and a second air gap under the second ILD layer.

14. The method according to claim 13, wherein the first air gap is taller than the first metal line and the second metal line, and the second air gap is shorter than the third metal line and the fourth metal line in height.

15. The method according to claim 13, wherein a cross section of the first air gap has a curved upper edge, and a cross section of the second air gap has a straight upper edge.

16. The method according to claim 13, wherein the first air gap is formed after forming the first metal line and the second metal line, and the second air gap is formed before forming the third metal line and the fourth metal line.

17. The method according to claim 13, wherein the first air gap is formed during deposition of the first ILD layer, and the second air gap is formed after forming the second ILD layer.

18. The method according to claim 13, wherein a sustaining layer is formed between the second ILD layer and the second air gap, the first air gap is formed during deposition of the first ILD layer, and the second air gap is formed after forming the sustaining layer and before forming the second ILD layer.

19. An interconnection structure, comprising:
a first interlayer dielectric (ILD) layer;
a first metal line and a second metal line adjacent to each other and disposed in the first ILD layer, where the first ILD layer has a first air gap disposed between the first metal line and the second metal line;
a metal via disposed in the first ILD layer, and disposed over and connected to the first metal line;
a second ILD layer disposed over the first ILD layer; and
a third metal line and a fourth metal line adjacent to each other and disposed in the second ILD layer, where the third metal line is disposed over and connected to the metal via, and is spaced apart from the fourth metal line by a second air gap under the second ILD layer.

20. The interconnection structure according to claim 19, wherein the first air gap has an oval cross section, and the second air gap has a polygonal cross section.
